(19) United States
(12) Patent Application Publication
(10) Pub. No.: US 2025/0294704 A1
(43) Pub. Date: Sep. 18, 2025

(54) CRYOGENIC CABINET

(71) Applicant: Psiquantum, Corp., Palo Alto, CA (US)

(72) Inventors: Hong Hu, Bothell, WA (US); Gabriel Catalano, San Mateo, CA (US); Ilya Vorobeichik, Los Gatos, CA (US)

(73) Assignee: Psiquantum, Corp., Palo Alto, CA (US)

(21) Appl. No.: 19/221,358

(22) Filed: May 28, 2025

Related U.S. Application Data
(63) Continuation of application No. PCT/US2023/081185, filed on Nov. 27, 2023.
(60) Provisional application No. 63/429,514, filed on Dec. 1, 2022.

(51) Int. Cl. H05K 7/20

(52) U.S. Cl. CPC H05K 7/20254; H05K 7/20263; H05K 7/20327; H05K 7/20372; H05K 7/20627; H05K 7/20663

(57) ABSTRACT

A cryogenic structure can include a cryogenic chamber that houses a plurality of circuits that operate and cryogenic temperatures, and a room temperature portion that houses a plurality of circuits that operate at non-cryogenic temperatures. The circuits can include computer chips, such as electrical or photonic chips, that are housed on movable structures that insertable into the cryogenic structure.

### CROSS-REFERENCES TO RELATED APPLICATIONS

This application is a continuation of International Patent Application No. PCT/US2023/081185, filed on Nov. 27, 2023, which claims priority to U.S. Provisional Patent Application No. 63/429,514, filed on Dec. 1, 2022, the disclosures of which are hereby incorporated by reference in their entirety for all purposes.

### BACKGROUND

A cryostat is a device that is used to maintain cryogenic temperatures (e.g., 120° K or less) for objects or materials located within the cryostat. Cryostats have been used for a number of applications in which cryogenic temperatures are implemented. For example, different types of high-performance computing (e.g., quantum computing, artificial intelligence based computers) may require cooling to extremely low temperatures for operation.

### BRIEF DESCRIPTION OF THE DRAWINGS

For a better understanding of the various described embodiments, reference should be made to the Detailed Description below, in conjunction with the following drawings in which like reference numerals refer to corresponding parts throughout the Figures.

FIG. 1 is a simplified schematic diagram illustrating an optical switch, according to some embodiments.

FIG. 2 is an illustration of a user interfacing with a hybrid quantum computing device, according to some embodiments.

FIG. 3 is a schematic top view of a modular cryogenic distribution system, in accordance with some example embodiments.

FIG. 4 is a schematic top view of a network of modular distributed cryogenic distribution systems, in accordance with some example embodiments.

FIGS. 5A and 5B are rear and front perspective views, respectively, of one pod of the modular distributed cryogenic distribution system of one embodiment.

FIG. 6 is a side cross-sectional view of the pod of FIGS. 5A and 5B.

FIG. 7A is a perspective view of a cryo-rack system, in accordance with some example embodiments.

FIG. 7B is a system diagram of control systems, in accordance with some example embodiments.

FIGS. 8A-8C show example vertical blade configurations, in accordance with some example embodiments.

FIGS. 9A-9C show example horizontal blade configurations, in accordance with some example embodiments.

FIG. 10 shows an example dilution refrigeration blade system, in accordance with some example embodiments.

FIG. 11A shows a cryoplant providing fluids to a blade system, in accordance with some example embodiments.

FIG. 11B shows an example blade rack system with four blade tower cabinets, in accordance with some example embodiments.

FIG. 11C shows a cryo-blade cube system, in accordance with some example embodiments.

FIG. 11D shows a front the of the cryo-blade cube system, in accordance with some example embodiments.

FIG. 12 shows an example cryogenic blade cabinet, in accordance with some

example embodiments.

FIG. 13 shows a side perspective view of the cabinet, in accordance with some example embodiments.

FIG. 14 shows a close-up of the cabinet, in accordance with some example embodiments.

FIG. 15 shows an example tray that can be inserted in the cabinet, in accordance with some example embodiments.

FIG. 16 shows support structures of the tray, in accordance with some example embodiments.

FIG. 17 shows a side perspective view of cryogenic cabinet 1200, in accordance with some example embodiments.

FIG. 18 shows a cabinet architecture, in accordance with some example embodiments.

While the features described herein may be susceptible to various modifications and alternative forms, specific embodiments thereof are shown by way of example in the drawings and are herein described in detail. It should be understood, however, that the drawings and detailed description thereto are not intended to be limiting to the particular form disclosed, but on the contrary, the intention is to cover all modifications, equivalents and alternatives falling within the spirit and scope of the subject matter as defined by the appended claims.

### SUMMARY

Embodiments herein relate generally to cryogenic systems, such as cryogenic systems used for high performance computing implementations having a modular distributed architecture.

### DETAILED DESCRIPTION

Reference will now be made in detail to embodiments, examples of which are illustrated in the accompanying drawings. In the following detailed description, numerous specific details are set forth to provide a thorough understanding of the various described embodiments. However, it will be apparent to one of ordinary skill in the art that the various described embodiments may be practiced without these specific details. In other instances, well-known methods, procedures, components, circuits, and networks have not been described in detail so as not to unnecessarily obscure aspects of the embodiments.

It will also be understood that, although the terms first, second, etc. are, in some instances, used herein to describe various elements, these elements should not be limited by these terms. These terms are used only to distinguish one element from another. For example, a first electrode layer could be termed a second electrode layer, and, similarly, a second electrode layer could be termed a first electrode layer, without departing from the scope of the various described embodiments. The first electrode layer and the second electrode layer are both electrode layers, but they are not the same electrode layer.

The following description, for purpose of explanation, is described with reference to specific embodiments. However, the illustrative discussions that follow are not intended to be exhaustive or to limit the scope of the claims to the precise forms disclosed. Many modifications and variations are possible in view of the above teachings. The embodiments were chosen to best explain the principles underlying the claims and their practical applications, to thereby enable others skilled in the art to best use the embodiments with various modifications as are suited to the particular uses contemplated.

A cryogenic cabinet can include a cryogenic chamber portion for housing cryogenic circuits (e.g., cryogenic temperature electronics and photonics chips and assemblies) and a non-cryogenic portion for housing non-cryogenic chips (e.g., room-temperature electronics and photonics chips and assemblies). The cryogenic chamber can include a temperature shield to provide thermal protection such that the cryogenic circuits can be maintained at a cryogenic temperature (e.g., 30 K, 4 K, 2 K). The temperature shield can be regulated by a first coolant, such as liquid nitrogen, and components inside the temperature shielded area can be regulated by a second coolant, such as liquid helium. The cryogenic chamber can include multiple plates and mounts for cooling and support of a scalable number of chips in a high-density configuration to enable high performance computing. Physical assemblies, such as trays, modules, and shelves, can house the cryogenic circuits and have guides or rails such that the physical assemblies can be easily removed and inserted into the cryogenic chamber.

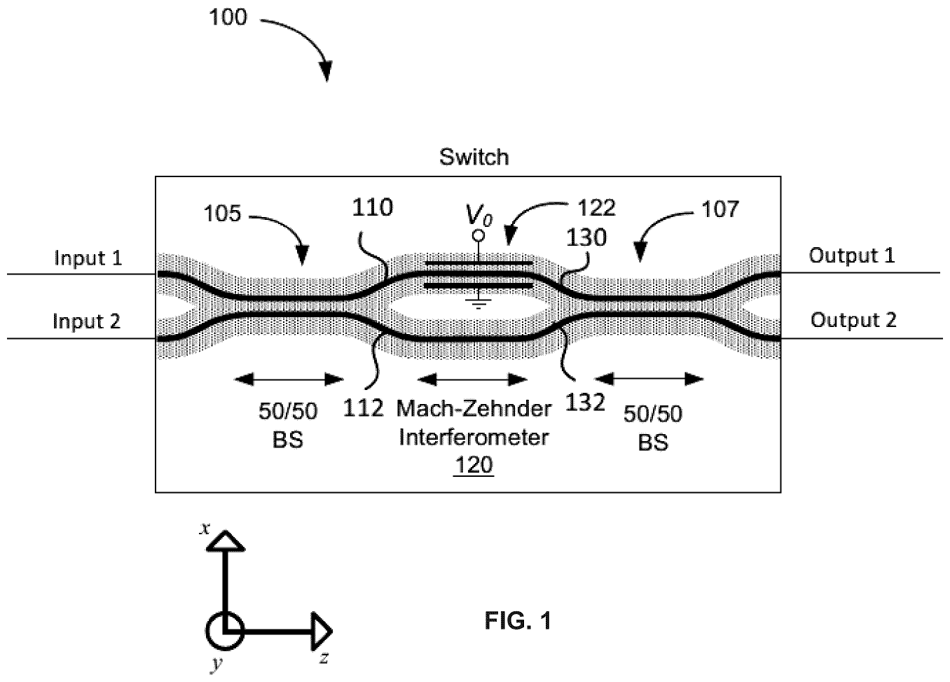

FIG. 1 is a simplified schematic diagram illustrating an optical switch according to an embodiment of this disclosure. Referring to FIG. 1, switch 100 includes two inputs: Input 1 and Input 2 as well as two outputs: Output 1 and Output 2. As an example, the inputs and outputs of switch 100 can be implemented as optical waveguides operable to support single mode or multimode optical beams. As an example, switch 100 can be implemented as a Mach-Zehnder interferometer integrated with a set of 50/50 beam splitters 105 and 107, respectively. As illustrated in FIG. 1, Input 1 and Input 2 are optically coupled to a first 50/50 beam splitter 105, also referred to as a directional coupler, which receives light from the Input 1 or Input 2 and, through evanescent coupling in the 50/50 beam splitter, directs 50% of the input light from Input 1 into waveguide 110 and 50% of the input light from Input 1 into waveguide 112. Concurrently, first 50/50 beam splitter 105 directs 50% of the input light from Input 2 into waveguide 110 and 50% of the input light from Input 2 into waveguide 112. Considering only input light from Input 1, the input light is split evenly between waveguides 110 and 112.

Mach-Zehnder interferometer 120 includes phase adjustment section 122. Voltage Vo can be applied across the waveguide in phase adjustment section 122 such that it can have an index of refraction in phase adjustment section 122 that is controllably varied. Because light in waveguides 110 and 112 still have a well-defined phase relationship (e.g., they may be in-phase, 180° out-of-phase, etc.) after propagation through the first 50/50 beam splitter 105, phase adjustment in phase adjustment section 122 can introduce a predetermined phase difference between the light propagating in waveguides 130 and 132. As will be evident to one of skill in the art, the phase relationship between the light propagating in waveguides 130 and 132 can result in output light being present at Output 1 (e.g., light beams are in-phase) or Output 2 (e.g., light beams are out of phase), thereby providing switch functionality as light is directed to Output 1 or Output 2 as a function of the voltage V₀ applied at the phase adjustments section 122. Although a single active arm is illustrated in FIG. 1, it will be appreciated that both arms of the Mach-Zehnder interferometer can include phase adjustment sections.

As illustrated in FIG. 1, electro-optic switch technologies, in comparison to all-optical switch technologies, utilize the application of the electrical bias (e.g., V₀ in FIG. 1) across the active region of the switch to produce optical variation. The electric field and/or current that results from application of this voltage bias results in changes in one or more optical properties of the active region, such as the index of refraction or absorbance.

Although a Mach-Zehnder interferometer implementation is illustrated in FIG. 1, embodiments of this disclosure are not limited to this particular switch architecture and other phase adjustment devices are included within the scope of this disclosure, including ring resonator designs, Mach-Zehnder modulators, generalized Mach-Zehnder modulators, and the like. One of ordinary skill in the art would recognize many variations, modifications, and alternatives.

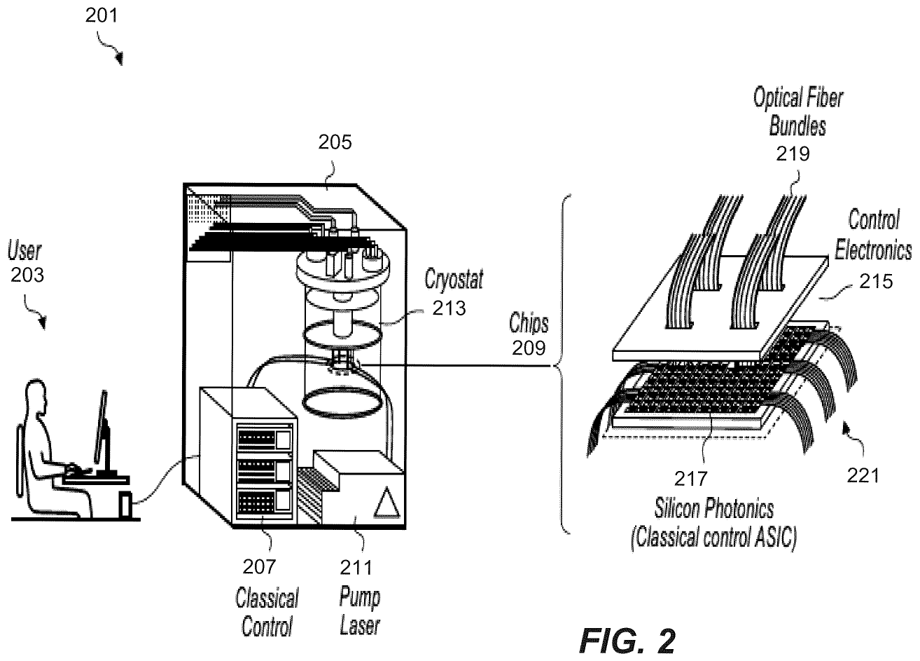

In some embodiments, the optical phase shifter devices described herein may be utilized within a quantum computing system such as the hybrid quantum computing system shown in FIG. 2. Alternatively, these optical phase shifter devices may be used in other types of optical systems. For example, other computational, communication, and/or technological systems may utilize photonic phase shifters to direct optical signals (e.g., single photons or continuous wave (CW) optical signals) within a system or network, and phase shifter architectures described herein may be used within these systems, in various embodiments.

FIG. 2 is a simplified system diagram illustrating incorporation of an electro-optic switch with a prior art cryostat into a hybrid quantum computing system, according to some embodiments. In order to operate at low temperatures, for example liquid helium temperatures, embodiments of this disclosure integrate the electro-optic switches discussed herein (e.g., see FIG. 1) into a system that includes cooling systems. Thus, embodiments of this disclosure provide an optical phase shifter that may be used within a hybrid computing system of the type illustrated in FIG. 2. The hybrid computing system 201 includes a user interface device 203 that is communicatively coupled to a hybrid quantum computing subsystem 205. The user interface device 203 may be any type of user interface device, for example, a terminal including a display, keyboard, mouse, touchscreen and the like. In addition, the user interface device may itself be a computer such as a personal computer (PC), laptop, tablet computer, etc.

In some embodiments, the user interface device 203 provides an interface with which a user can interact with the hybrid quantum computing subsystem 205. For example, the user interface device 203 may run software, such as a text editor, an interactive development environment (IDE), command prompt, graphical user interface, and the like so that the user can program, or otherwise interact with, the QC subsystem to run one or more quantum algorithms. In other embodiments, the hybrid quantum computing subsystem 205 may be pre-programmed and the user interface device 203 may simply be an interface where a user can initiate a quantum computation, monitor the progress, and receive results from the hybrid quantum computing subsystem 205. The hybrid quantum computing subsystem 205 may further include a classical computing system 207 coupled to one or more chips 209 (e.g., quantum computing chips, electronic chips, controller chips, logic circuits). In some examples, the classical computing system 207 and the chips 209 can be coupled to other electronic components, e.g., pulsed pump lasers 211, microwave oscillators, power supplies, networking hardware, etc.

The chips 209 may be housed within a cryostat, for example, cryostat 213. In some embodiments, each of the chips 209 can include one or more constituent chips, e.g., electronic chip 215 and photonic integrated circuit (PIC) chip 217. The PIC chip 217 may include the switch 100 (e.g., interferometer), discussed above with reference to FIG. 1. Signals can be routed on- and off-chip any number of ways, e.g., via optical interconnects 219 (e.g., optical fiber bundles) and via other electronic interconnects 221.

Prior art large scale cryogenic distribution systems, such as the ones shown in FIG. 2, do not allow for high numbers of separate payloads to be interfaced and cooled without the entire cryogenic system warming up or changing status. This limits the flexibility of having multiple different cryogenic chambers that can interface devices together due to the different life and service cycles of these devices within the system. Such prior art large scale systems do not have modularity built into the distribution scheme for the cryogenic routing and connections and thus cannot accommodate the increased number of individual payloads. Such prior art cryogenic systems do not allow for the independent warming and cooling of individual cryogenic pods because they lack individual modules for payloads.

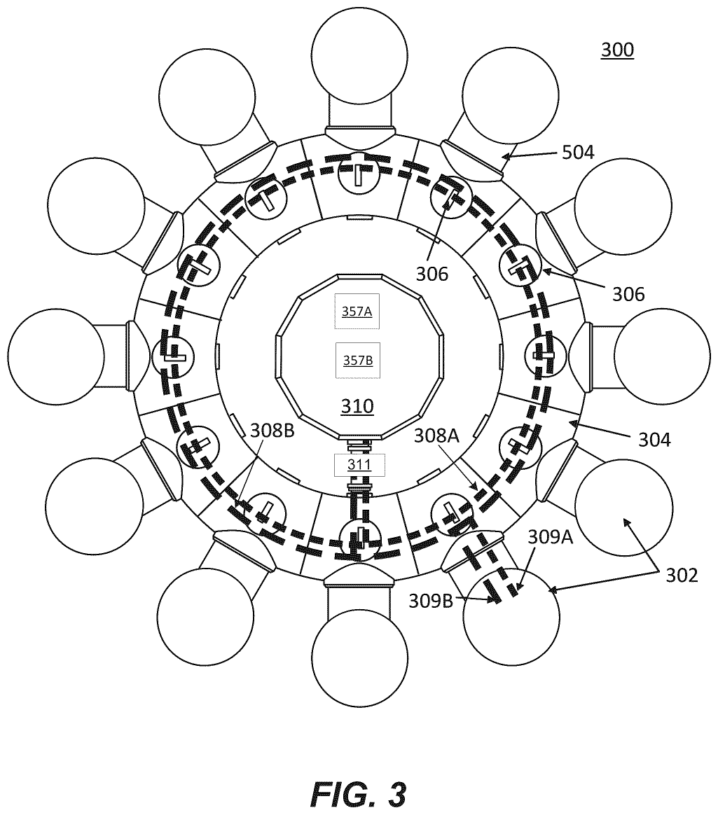

FIG. 3 is a schematic top view of a modular cryogenic system 300, in accordance with some example embodiments. In the illustrated example of FIG. 3, a modular cryogenic system 300 (e.g., a cryogenic loop or ring system) a cryogenic distribution system is separated into multiple individual cryochambers (e.g., pods) that are attached to a common chamber 304 (e.g., loop enclosure, toroid, enclosed hoop) that houses cryogenic fluid conduits 308A, 308B. The cryogenic fluid conduits 308A, 308B (e.g., pipes) are fluidly connected to the associated valves 306 and feedthrough conduits 309A, 309B into each cryochamber 302 for control. In some example embodiments, the common chamber 304 is an enclosure that is shaped as a toroidal loop. However, in other embodiments, the common chamber 304 may have other shapes (e.g., non-loop shapes), such as linear, curved, zig-zag, and so on. The common chamber 304 can be maintained at a vacuum to provide a controlled environment to connect each of the cryochambers (e.g., cryochamber 302) to one another to implement data interconnects between the nodes. In some example embodiments, the common chamber 304 comprises the coolant circulant system as well as optical interconnects (e.g., bundles of optical fiber) and electrical interconnects (e.g., cables) to connect the cryochambers through their respective interfaces to the common chamber 304. In some example embodiments, the optical interconnects in the common chamber transfer quantum light (e.g., photonic qubits, resource states, Greenberger-Horne-Zeilinger (GHZ) entangled states) between the chambers and the common chamber 304 provides a controlled environment that protects the optical interconnects from temperature changes and physical movement, which may otherwise disrupt or decohere the quantum light on the optical interconnects.

While two conduits 308A and 308B are shown in dashed lines as extending inside the common chamber 304 (e.g., toroidal loop enclosure), four or more conduits may be provided. For example, the conduits 308A and 308B may comprise liquid helium inlet and outlet conduits, respectively. If the modular cryogenic system 300 uses both liquid helium and nitrogen, the additional liquid nitrogen inlet and outlet conduits may be provided inside the common chamber 304 enclosure.

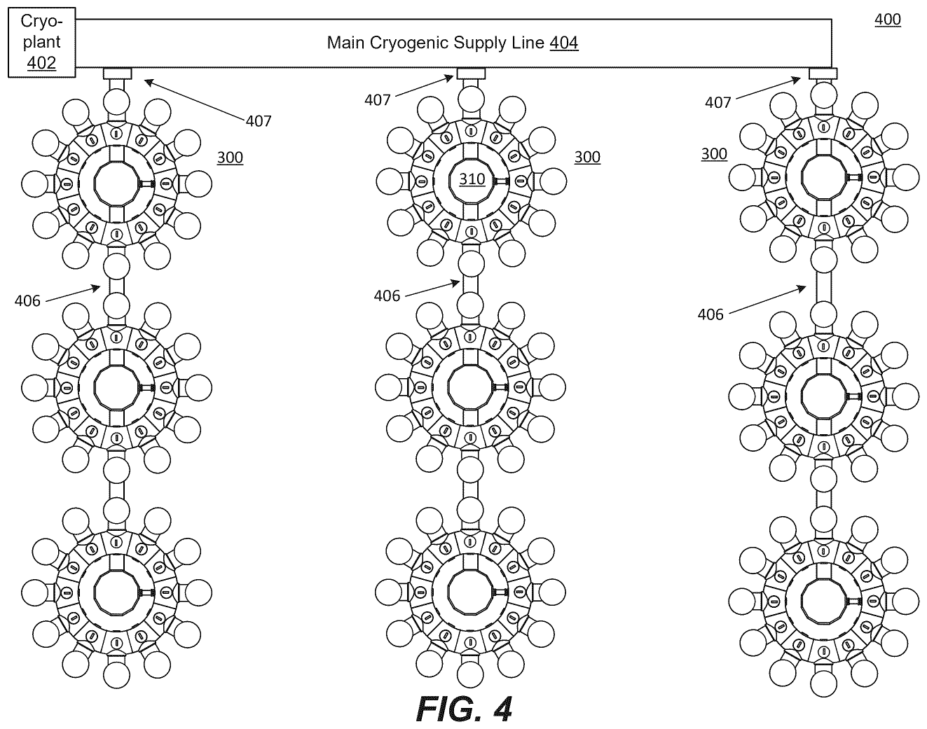

In the illustrated example of FIG. 3, the common chamber 304 has a circular shape (e.g., viewed from the top). However, in other embodiments, the common chamber 304 may have a polygonal (e.g., triangular, rectangular, hexagonal, etc.), an oval or an irregular shape. The embodiment shown in FIG. 3 includes a distribution scheme that is based upon a circular geometry with all the payloads (e.g., electronic chips, photonic integrated circuit chips) in separate cryochambers (e.g., “pods”) are arrayed around the outside of the common chamber 304. In other embodiments, the cryochambers may be arrayed inside, above and/or below the common chamber 304 in addition to or instead of outside the common chamber 304. The center of the ring-shaped loop contains the hub 310 for connection into a larger cryogenic system (e.g., modular cryogenic distribution system 400, FIG. 4; a cryoplant).

In some example embodiments, the common chamber 304 comprises several sections that combine to form the overall loop and provide an interface into the loop for the cryogenic connections and other input/outputs. Each common chamber 304 loop provides independent control over each attached payload in the respective cryochamber 302 using the valves 306. In this way, different pods can be individually cooled down for operation and warmed up to access components in a given pod.

The modular cryogenic system 300 allows the integration of many pods into a large cryogenic supply of both liquid helium and nitrogen without the disruption of other cryochambers (e.g., cryochamber 302) or the liquefaction of the cryogenic supply. Each distributed cryogenic pod is just one section of a loop (e.g., ring) that can contain more pods as the radius of the common chamber 304 increases. Each pod is a section of the common chamber 304, and each common chamber 304 is connected to the large cryogenic supply lines through the hub 310. The pods have valves 306 (e.g., control valves) to turn off and on the flow of the cryofluid (e.g., liquid helium and nitrogen) into the cryochamber 302 from the common chamber 304. Depending on the overall desired system size, each modular cryogenic system 300 may have a desired number of pods, and the number of modular cryogenic distribution systems in the modular cryogenic distribution system 400 can be varied to meet the level of flexibility desired for cycle time and testing. During normal full system operation, all the valves 306 are open and the devices (e.g., chips) within the cryochambers are interfaced to the cooling mechanism (e.g., the main cryoplant 402). When a fault is detected and a need arises to open one pod, the valves 306 for the specific pod close and heaters bring the cryochamber 302 to ambient conditions allowing for service access once vented (e.g., raised to atmospheric pressure) via a pod vent (e.g., to room temperature, ambient pressure of the room or environment), while the rest of the pods in the modular cryogenic system 300 continue to operate at cryogenic temperatures.

If a larger number of pods require service or changeover, the modular cryogenic system 300 can be closed off from the main cryogenic supply line (e.g., main cryogenic supply line 404, branch supply line 406, FIG. 4) by closing valves in the modular cryogenic distribution system.

The modular cryogenic system 300 and the modular cryogenic distribution system 400 provide an improved level of control and access compared to prior art large-scale cryogenic systems. The modular cryogenic system 300 is suitable for the large-scale cryogenic computing tasks that interfaces a multitude devices (e.g., chips) with a cryocooling source while maintaining flexibility for cycle time and individual unit accessibility.

In some example embodiments, a cryochamber (e.g., cryochamber 302) comprises a respective set of valves 306, heaters, and feedthroughs that connect into the common chamber 304 of the modular cryogenic system 300 through a respective bulkhead (e.g., bulkhead interface to a given pod). In some example embodiments, each pod further comprises a rough pump valve to couple to a vacuum pump (e.g., rough pump, manual pump) of the pod to place the pod in low or rough vacuum before the pod vacuum valve (e.g., a gate valve) is opened to the loop chamber.

FIG. 4 is a schematic top view of a network of modular distributed cryogenic distribution systems, in accordance with some example embodiments. As shown in the example of FIG. 4, a main cryoplant 402 provides the cryofluid (e.g., liquid helium and/or nitrogen) to the main cryogenic supply line 404. The main cryoplant 402 may comprise any suitable cryoplant, such as a Stirling cryoplant or pulse tube cryoplant. The cryofluid is distributed from the main cryogenic supply line 404 to branch supply lines 406. The branch supply lines 406 are fluidly connected to the hubs 310 of the respective modular distributed cryogenic distribution systems (e.g., the modular cryogenic system 300 shown in FIG. 3). In some example embodiments, each branch line comprises a supply line valve 407 to fluidly isolate a set of cryogenic loops from the cryoplant 402. In some example embodiments, the hub 310 comprises a liquid helium coolant storage tank 357A and a liquid nitrogen coolant storage tank 357B for storage and circulation of the different cryogenic coolants. In some example embodiments, the hub 310 comprises liquefiers (e.g., a condenser/cold head to recondense the cryo-fluid (e.g., helium)), a vacuum pump to maintain the hub 310 at vacuum, the common chamber 304 and the pods at vacuum (e.g., at a pressure of about 10\hat{ }−6 torr), and valves. The central hub 310 is fluidly connected to the main cryogenic supply line 404 and functions as a buffer and control node for each modular distributed cryogenic distribution system. Thus, the hubs 310 provide control over the attached payloads for the given common chamber 304. In some example embodiments, each hub 310 comprises one or more hub valves 311 to fluidly isolate the hub 310 and therefor the modular cryogenic system 300 from the branch supply line 406 and cryoplant 402.

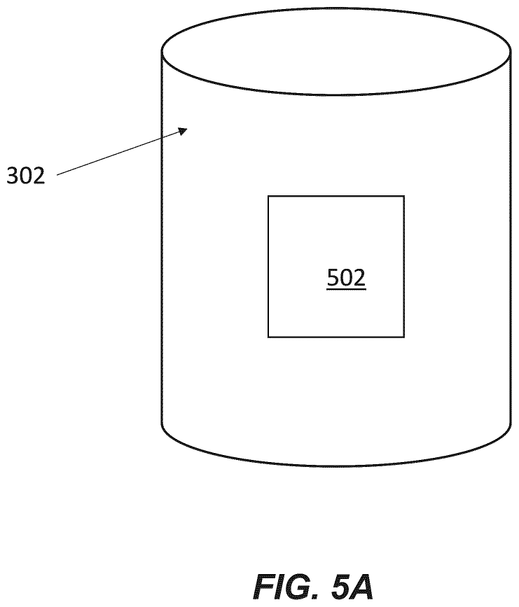

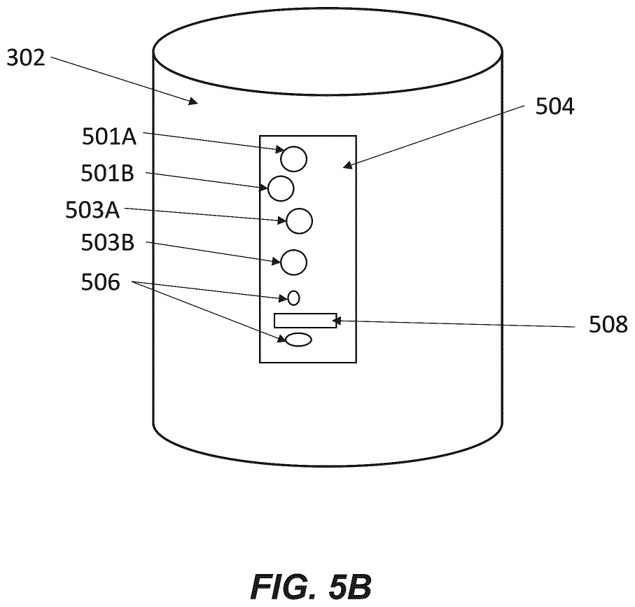

FIGS. 5A and 5B illustrate the rear and front views of one of the cryochambers, in accordance with some example embodiments. As shown in FIG. 5A, the back (rear) side of the cryochamber 302 which faces away from the common plenum (e.g., loop) 304 has a door 502. The door 502 may be opened by service personnel to service the components inside the cryochamber 302.

As shown in FIG. 5B, the front side of the cryochamber 302 which faces the common chamber 304 (e.g., loop) contains the bulkhead 504. The bulkhead 504 provides access from the common chamber 304 to the cryochamber 302. The bulkhead 504 may contain various feedthroughs (i.e., openings). In other embodiments, if the cryochamber 302 is located below the common chamber 304 instead of radially outwards of the common chamber 304, then the bulkhead 504 may be located on top of the cryochamber 302 instead of on the front side of the cryochamber 302.

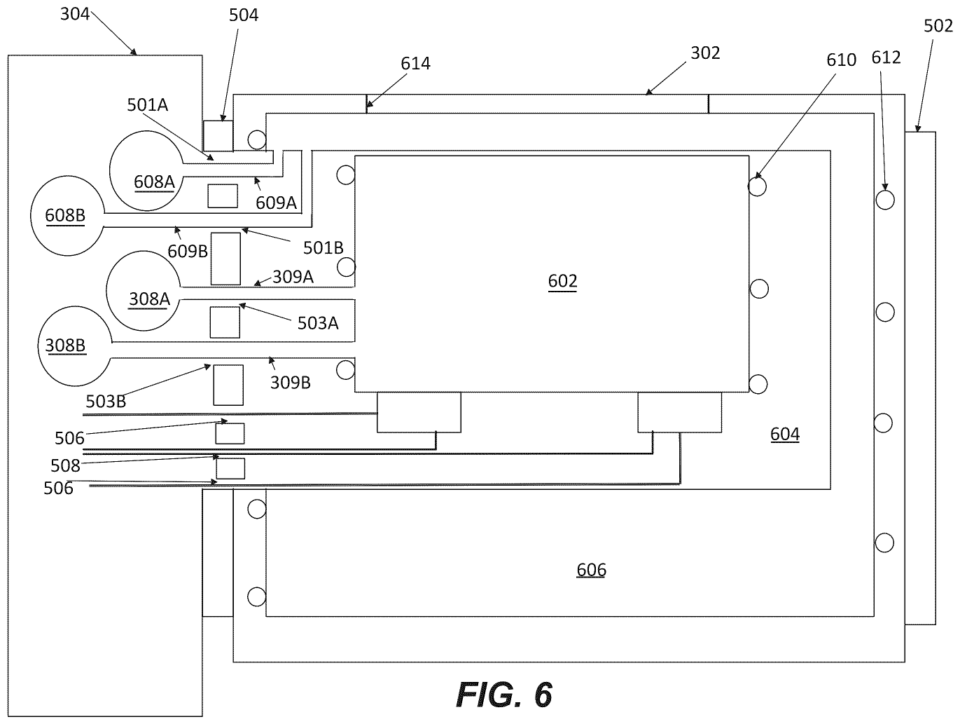

As shown in FIGS. 5B and 6, the common chamber 304 may comprise a vacuum chamber which houses liquid nitrogen inlet and outlet conduits 608A and 608B, respectively. Liquid nitrogen inlet and outlet feedthrough conduits 609A and 609B may extend through their respective feedthroughs 501A and 501B in the bulkhead 504. The conduits 609A and 609B are fluidly connected through the feedthroughs to the liquid nitrogen inlet and outlet conduits 608A and 608B, respectively, which are located inside the common chamber 304.

Liquid helium inlet and outlet feedthrough conduits 309A and 309B may extend through their respective feedthroughs 503A and 503B in the bulkhead 504. The conduits 309A and 309B are fluidly connected through the feedthroughs to the liquid helium inlet and outlet conduits 308A and 308B, respectively, which are located inside the common chamber 304.

Optical interconnects 219 (e.g., optical fiber bundles) extend from the common chamber 304 into the cryochamber 302 through feedthroughs 508. Electronic interconnects 221 (e.g., DC and/or RF buses and/or wires) extend from the common chamber 304 into the cryochamber 302 through feedthroughs 506. The interconnects may pass from the common chamber 304 into the central hub 310 and then out to the remaining quantum computer components described above.

As shown in FIG. 6, the cryochamber 302 contains a liquid helium chamber 602, a vacuum plenum 604 and a liquid nitrogen chamber 606 (e.g., a liquid nitrogen cooled thermal shield). The liquid helium chamber 602 contains liquid helium during operation of the modular cryogenic system 300. The liquid helium is cycled to the liquid helium chamber 602 through conduits 308A and 309A, and is cycled away from the liquid helium chamber 602 through conduits 308B and 309B. Thus, liquid helium is routed to and from the liquid helium chamber 602 via conduits 308A and 308B located in the common chamber 304 and through feedthrough conduits 309A and 309B which extend from the common chamber 304 into the cryochamber 302 through the bulkhead 504.

The liquid helium chamber 602 may be located in the vacuum plenum 604 of the cryochamber 302. The vacuum plenum 604 may be fluidly connected to the common chamber 304 via the feedthroughs in the bulkhead 504. Thus, when the common chamber 304 is pumped down to a vacuum (e.g., by a vacuum pump located in the hub 310), the vacuum plenum 604 is also pumped down to vacuum at the same time. The feedthrough conduits 309A and 309B may be fluidly connected to the liquid helium chamber 602 through the bulkhead 504 to cycle liquid helium to and from the liquid helium chamber 602.

The chips 209 described above may be placed in thermal contact (such as direct or indirect physical contact) with the liquid helium chamber 602. For example, the chips 209 may be attached directly or via an interposer to the bottom of the liquid helium chamber 602. In other embodiments, the chips 209 may be placed on different surface(s) of the liquid helium chamber 602, such that the liquid helium in the liquid helium chamber 602 cools the chips 209 to a temperature of 4.2 K or below, such as 2-4K. Thus, the chips 209 may be located in the vacuum plenum 604 below the liquid helium chamber 602.

The optical interconnects 219 and the electronic interconnects 221 are connected to the chips 209 (e.g., from below and/or from the sides). The optical interconnects 219 and the electronic interconnects 221 extend through the vacuum plenum 604 to the respective feedthroughs in the bulkhead 504.

The liquid nitrogen chamber 606 may at least partially surround the vacuum plenum 604 and the liquid helium chamber 602. The liquid nitrogen chamber 606 provide a thermal shield to the liquid helium chamber 602. The feedthrough conduits 609A and 609B cycle liquid nitrogen to and from the liquid nitrogen chamber 606. The liquid nitrogen chamber 606 may include a nitrogen shield and contain liquid nitrogen during operation, which is maintained at a temperature of about 77K.

A first heater 610 may be located adjacent to liquid helium chamber 602 to warm up the liquid helium chamber 602 when the cryochamber 302 is being serviced or shut off. A second heater 612 may be located adjacent to liquid nitrogen chamber 606 to warm up the liquid nitrogen chamber 606 when the cryochamber 302 is being serviced or shut off. The heaters 610 and 612 may comprise independently controlled resistive heaters which are located at least one sidewalls of their respective chambers.

The liquid helium chamber 602, the vacuum plenum 604 and/or the liquid nitrogen chamber 606 may be attached to the cryochamber 302 using any suitable mechanical connections. For example, they may be suspended from the top of the cryochamber 302 using rods 614. Alternatively, they may be attached to the bottom and/or the side of the pod using one or more of rods, plates, brackets, and so on.

Thus, the modular cryogenic system 300 of one embodiment, and the modular cryogenic distribution system 400, may be used in a quantum computing device described above. The modular cryogenic system 300 contains separate cryopods (e.g., cryochamber 302) housing chips 209 (e.g., photonic integrated circuit chips, electronic chips) of the quantum computing device.

In other embodiments, a server rack style cryostat with blade-based high density packing of cryogenic and room temperature electro-optical assemblies is provided. The cryostat provides a way to assemble a high number of chips 209 into a finite volume, which need to be cryogenically cooled to function correctly. The cryostat contains vertically assembled blade-style rack to mount the chips 209. The cryostat is compatible with multiple system designs and can be upgraded to provide dilution refrigeration as well.

The cryostat has two configurations, a helium-4 configuration (e.g., thermosiphon cryogenic technology) and a dilution configuration. In the helium-4 configuration, there are two arrangements of T0SAs (low temperature “T0” sub-assemblies), one arrangement at cryogenic temperatures, one at room temperature. One cryostat is comprised of a cryo-cabinet (i.e., vacuum chamber and liquid cryogen vessel) and multiple cryo-blades (e.g., liquid cooled cold plates).

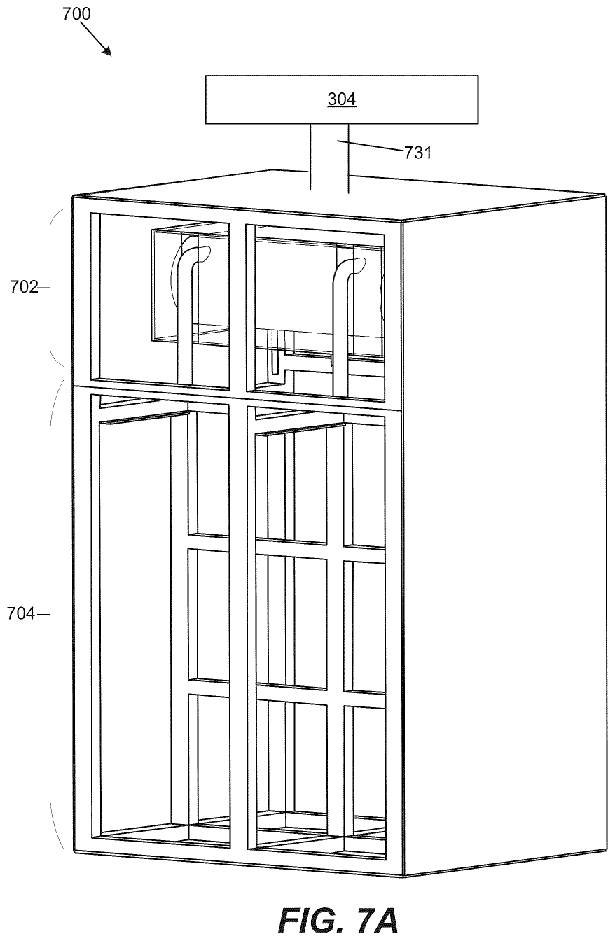

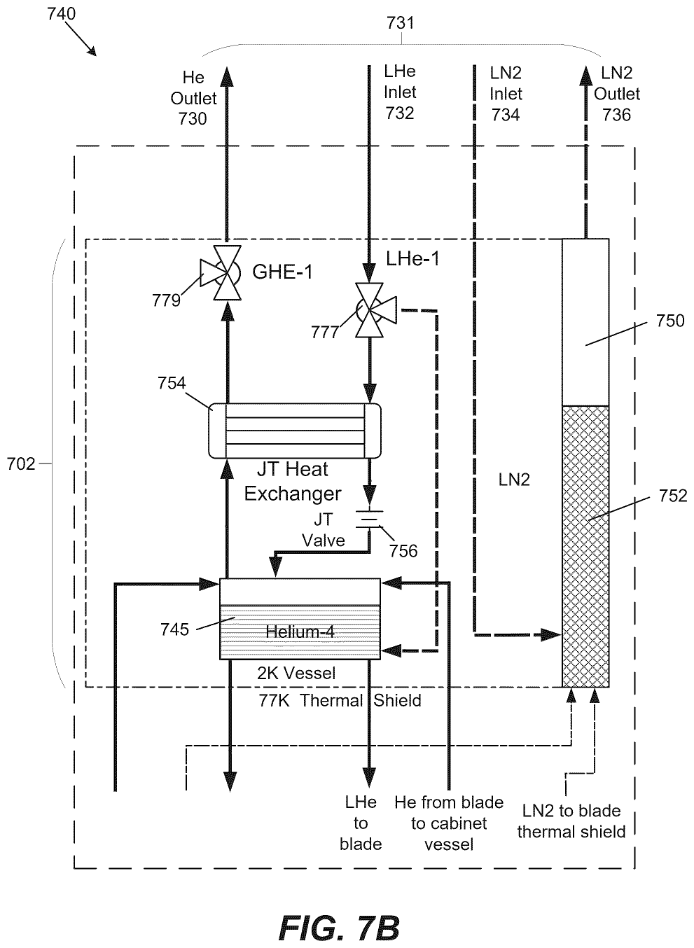

FIG. 7A shows an example cryogenic cabinet system 700 (e.g., cryogenic quantum computer data rack system) without blade systems, in accordance with some example embodiments. In the illustrated example, the cryogenic cabinet system 700 can house four cryostat blade towers (e.g., cryogenic blade tower 800, cryogenic blade tower 900) in a tower cabinet area 704 of the cryogenic cabinet system 700. An example cryo-cabinet system diagram 740 is shown in FIG. 7B. The cryogenic cabinet system 700 comprises a distribution top section 702 that comprises tanks and control systems (e.g., valves) to input and output fluids from the plurality of towers. The distribution top section 702 and the tower cabinet area 704 are part of a single vacuum chamber, in accordance with some example embodiments. The cryogenic cabinet system 700 can be implemented as a single cryopod (e.g., pod, cryochamber 302), in which the cryogenic cabinet system 700 one or more fluid conduits 731 to couple to the common chamber 304 as discussed above (e.g., for vacuum pumping, to couple in and couple out cryogenic fluids). The cryogenic cabinet system 700 has a liquid helium-4 vessel 745 (e.g., tank) and a liquid nitrogen-cooled thermal shield 750, where the thermal shield 750 is cooled by a liquid nitrogen vessel 752 (e.g., tank, LN2 vessel, one or more LN2 tubes), all housed in the cryogenic cabinet system 700 under vacuum (e.g., 10\hat{ }−6 millibar) for thermal isolation and convection mitigation. The liquid helium and liquid nitrogen are supplied from a cryoplant in some example embodiments. The helium outlet 730, liquid helium inlet 732, liquid nitrogen inlet 734, and liquid helium outlet 736 can couple the cryo-fluids into and out of the cryogenic cabinet system 700. A helium valve 777 (e.g., liquid helium valve) and second helium valve 779 (e.g., helium gas valve) may further be implemented to couple the helium into and out of the cabinet. The helium outlet 730 is connected to a helium-4 recovery system. A Joule-Thompson (JT) heat exchanger 754 and JT valve 756 are implemented to bring the liquid helium saturation temperature to sub 4K (e.g., enable liquid helium working at sub-atmosphere region, where saturation temperature is below 4k). In some example embodiments, the cryogenic blade is thermally connected to the main helium vessel and liquid nitrogen cooled thermal shield but is physically separated except for pipes (cryo-pipes).

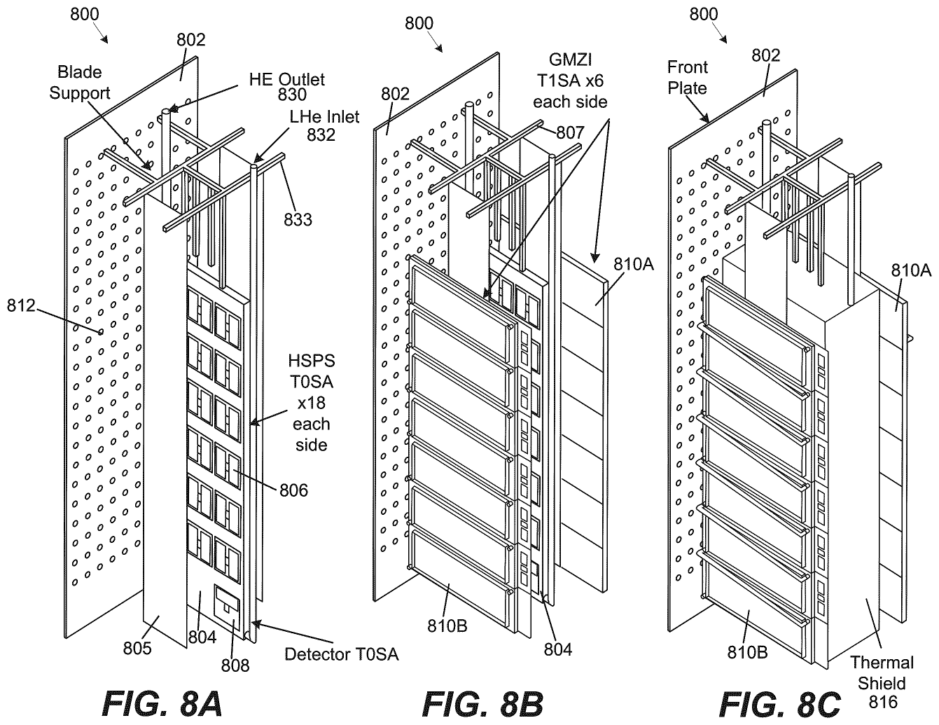

FIGS. 8A-8C show an example cryogenic blade tower 800 (e.g., vertical rack system), in accordance with some example embodiments. In particular, FIG. 8A shows the cryogenic blade 804 (e.g., metal cold plate assembly, primary cold plate, cryogenic plate); FIG. 8B shows an installation of the room temperature blades, including first room temperature blade 810A and second room temperature blade 810B (e.g., higher temperature “T1” chips (TISA), metal non-cryogenic blades having water circulation pipes for water cooling, electronic and photonic chip higher temperature blades); and FIG. 8C shows an installation of the liquid nitrogen cooled thermal shield 816 (e.g., cryo-blade thermal shield, copper thermal radiation shield). The cryogenic blade tower 800 has a cryogenic blade 804 in the middle to mount photonic chips (e.g., PIC chip 217, FIG. 2) with PIC single photon sources 806 and PIC superconducting single photon detectors 808. The liquid helium inlet 832 and helium outlet 830 are two pipes that connect to the cryogen vessel (e.g., Helium tank or vessel). In some example embodiments, a cryogenic pipe is routed around the perimeter of the cryogenic blade 804. The room temperature control electronics (e.g., chip 215, FIG. 2) are installed on two room temperature blades 810 adjacent and parallel to the cryogenic blade 804. The blades can be rigidly attached (e.g., with fasteners) to structural panels and frames, such metal panel 805 and frame 807. The structural supports (e.g., panels and frames) can be attached to the cryo-rack system, or attached inside a single tower cabinet that slides in and out from the rack system (e.g., cryogenic cabinet system 700; multi-tower system). In some embodiments, the room temperature blades 810 are cooled by flowing room temperature water or dielectric fluid around pipes of the room temperature blades 810 (water pipes not depicted) to prevent overheating of electrical equipment in vacuum where air cooling is not available. In some example embodiments, optical interconnects (e.g., fiber optic cables) and electrical interconnects (e.g., ribbon cable, electrical wiring) is connected to the chips inside the cabinet through a plurality of feedthroughs 812 of an access panel 802 (tower front panel) for the cryogenic blade tower 800. In some example embodiments, the cabinet includes a blade support metal frame structure 833 to support the cabinet in the larger cryo-cube system (e.g., cryogenic cabinet system 700). It is appreciated that the room temperature blades 810 may in some environments have a temperature that is the same as the physical environment in which the cabinet is located (e.g., data center room), and further the room temperature blades 810 may be colder than the surrounding environment temperature due to the dielectric or water cooling).

In the between of cryogenic electronics on the cryogenic blade 804 and room temperature electronics on the room temperature blades 810, there is a cryogenically cooled thermal shield 816 to reduce the radiation heat transfer and provide thermal lagging for cables and wires running between the room temperature blades 810 and cryogenic blade 804. In accordance with some example embodiments, each thermal shield 816 is thermally connected to a larger thermal shield encompassing most of the volume of the cryo-cabinet.

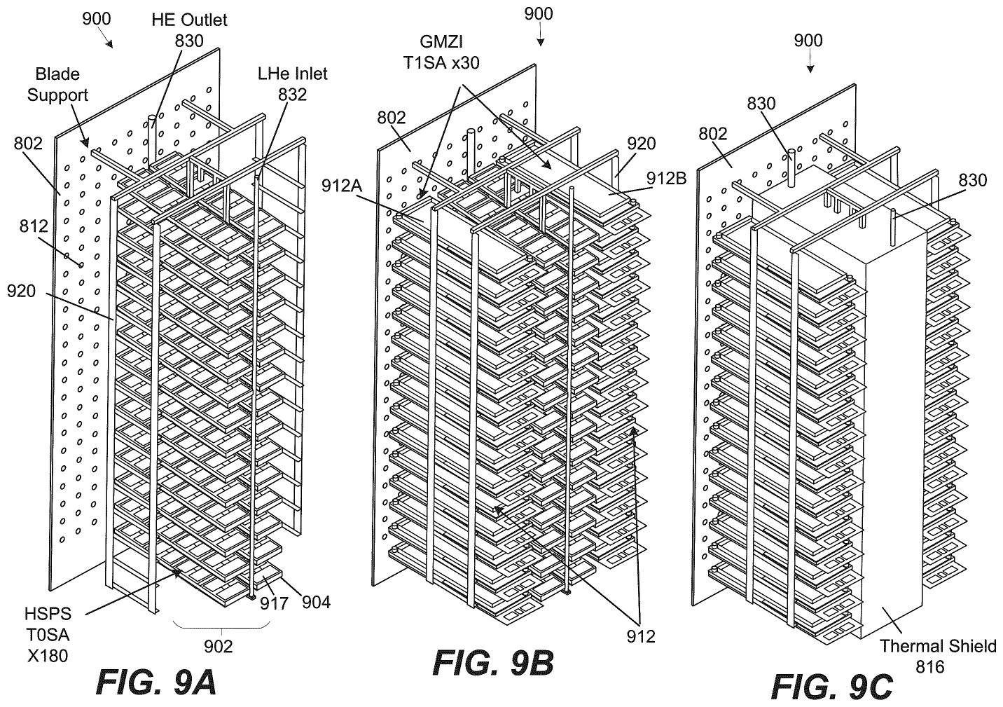

FIG. 9A-9C show an example cryogenic blade tower 900 (e.g., horizontal rack system), in accordance with some example embodiments. FIG. 9A shows the horizontal mounted cryogenic blades 902 (e.g., horizontal cold plate assembly) having a plurality of cryogenic dies, such as photonics chip 917 (e.g., photon detector). FIG. 9B shows the installation of the higher temperature electronics on horizontal room temperature blades 912 (e.g., horizontal plate stack 912A, horizontal plate stack 912B). In some example embodiments, the horizontal structure further includes a metal frame 920 to support the horizontal chip mounts of the cold plate blade and the higher temperature (e.g., room temperature blade). FIG. 9C shows the installation of the liquid nitrogen cooled thermal shield 816. The example embodiments of FIGS. 9A-9C enable house and manage more cryo-chips (e.g., die, photonics chip, chip sub-assemblies) than the embodiments of FIG. 8A-8C, due to more chips being installable on the horizontal mounted cryogenic blades 902 (e.g., horizontal cold plate assembly comprising horizontal mounting cold plates), although this requires a lower heat load for each die (e.g., photonics chip 917). In other respects, the basic structure is same as the first embodiment, with the exception that the horizontal mounting cold plates 904 (e.g., metal horizontal shelf structures attached to cold plate) are arranged approximately horizontally rather than vertically as in FIG. 8A-8C. In this embodiment of FIG. 9A-9C, the cryo-chips are installed on both upper and bottom surfaces of the smaller horizontal mounting cold plates 904 which have a slight incline angle between liquid helium inlet 832 and helium outlet 830. The room temperature chips are installed horizontally next to the cryogenic chips (e.g., a plurality of chips, photonics chip 917) with a thermal shield in between.

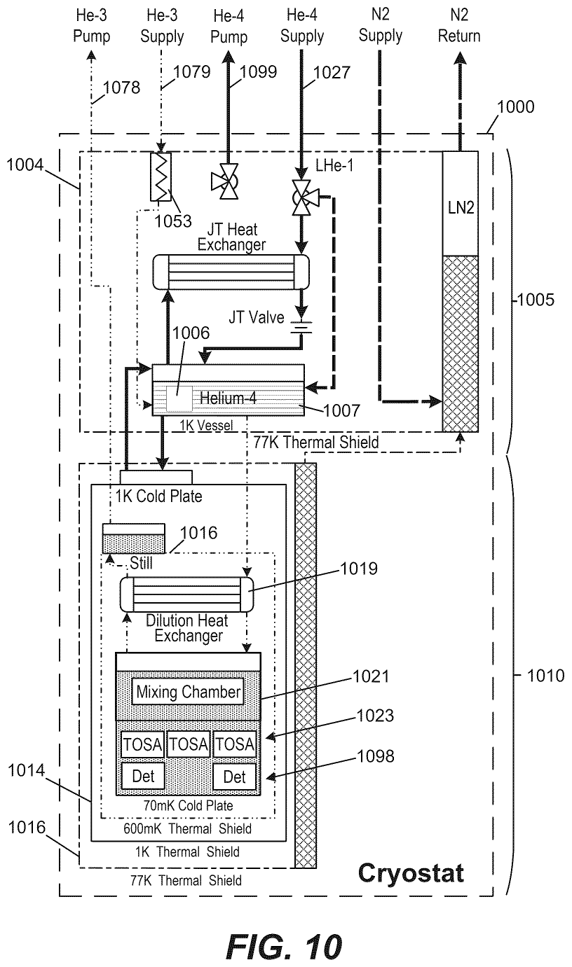

FIG. 10 shows a dilution refrigeration cryo-blade cabinet rack 1000, in accordance with some example embodiments. In the dilution refrigeration cryo-blade cabinet rack 1000 of FIG. 10, the distribution top section 1005 includes control systems to distribute the cryo-fluids to a tower cabinet section 1010 that houses one or more blade towers. In the embodiment of FIG. 10, multiple thermal shields at different temperatures are implemented. The dilution configuration of FIG. 10 can implement a flow process that is similar to a “wet” dilution refrigerator. In the distribution top section 1005, the helium vessel 1007 (e.g., liquid helium-4 bath) is pumped to a lower temperature (e.g., 1.2K) than the embodiments discussed above (e.g., FIGS. 8A-8C, FIGS. 9A-9C, operating at 2.2K). The helium-3 is cycled and pumped into the dilution refrigeration cryo-blade cabinet rack 1000 through a helium-3 inlet 1079 and outlet 1078, independent from the helium-4 lines: a helium-4 inlet 1027 and helium-4 outlet 1099 (e.g., the latter being connected to a Helium pump), in accordance with some example embodiments.

In accordance with some embodiments, the helium-3 is pre-cooled in a helium-3 vessel 1053 by liquid nitrogen pipes that cool the thermal shield 1004. The helium-3 flows through the heat exchanger 1006 inside the helium vessel 1007. The helium-3 temperature at the outlet of this heat exchanger is around 1.3K. Helium-3 is also cooled by the still thermal shield 1016 (˜600 mK). Then, the helium-3 is further cooled by the exhausting helium-3 gas in the dilution heat exchanger 1019 to 70 mK. In some embodiments, the mixing chamber 1021 functions at 50 mK to 70 mK, with a cooling capacity of approximately 800 μW. The cryo-chips 1023 (e.g., TOSAs, single photon source PICs, detector PICs) are installed on the copper-made cold plate 1098, which is attached to the bottom surface of the mixing chamber 1021. In some embodiments, the optical fibers and electrical wiring are thermal lagged on each thermal shield (e.g., a 660 mk to 1 k thermal shield 1014, 77 k thermal shield 1016).

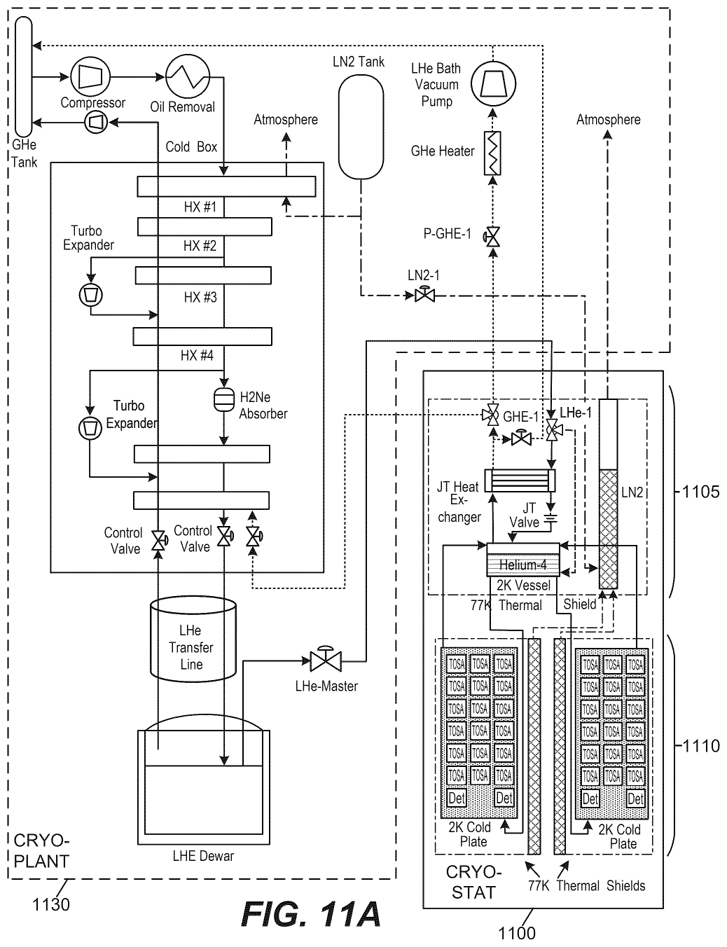

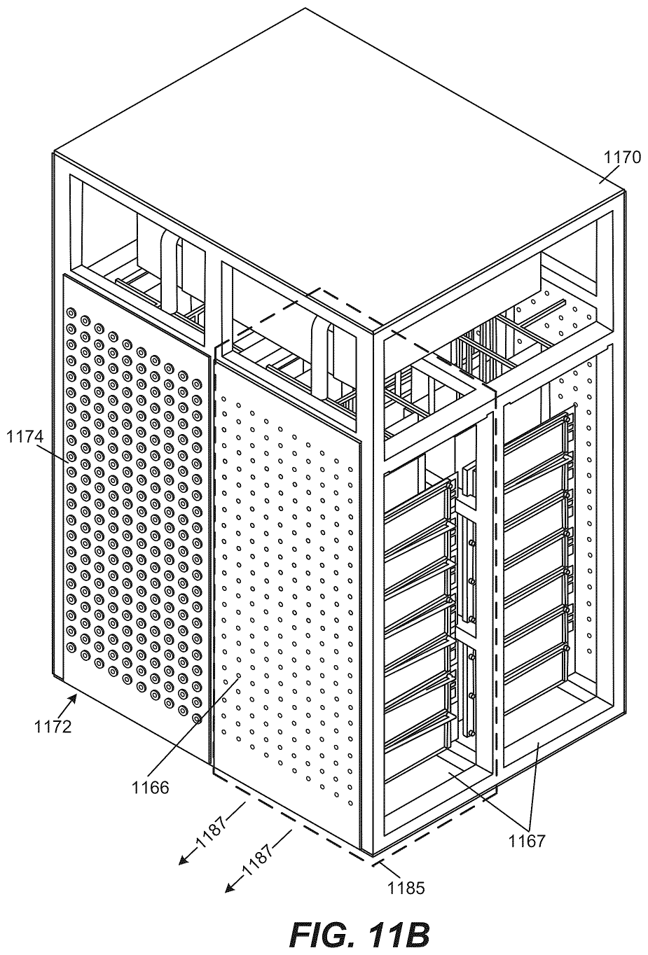

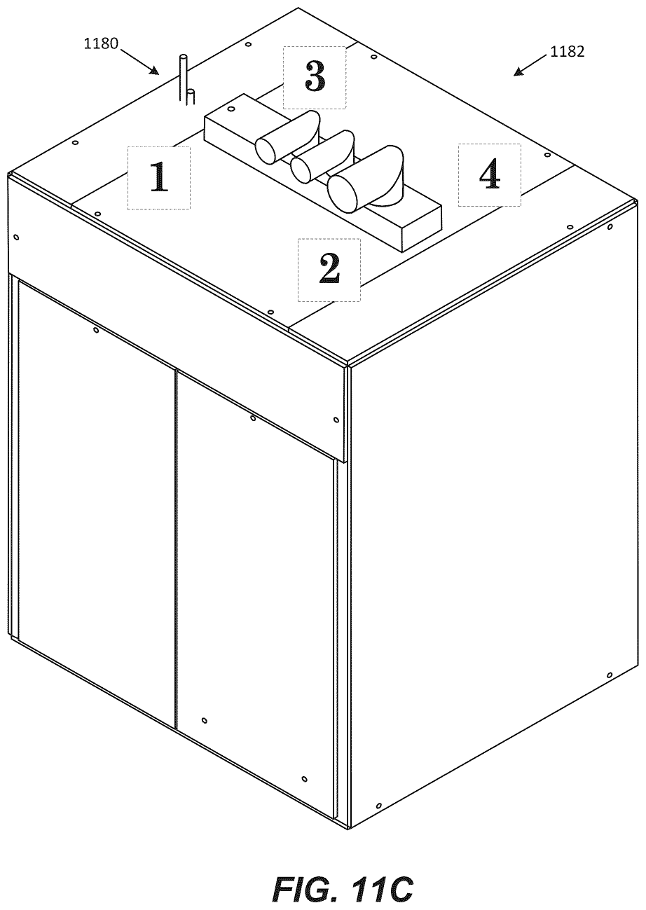

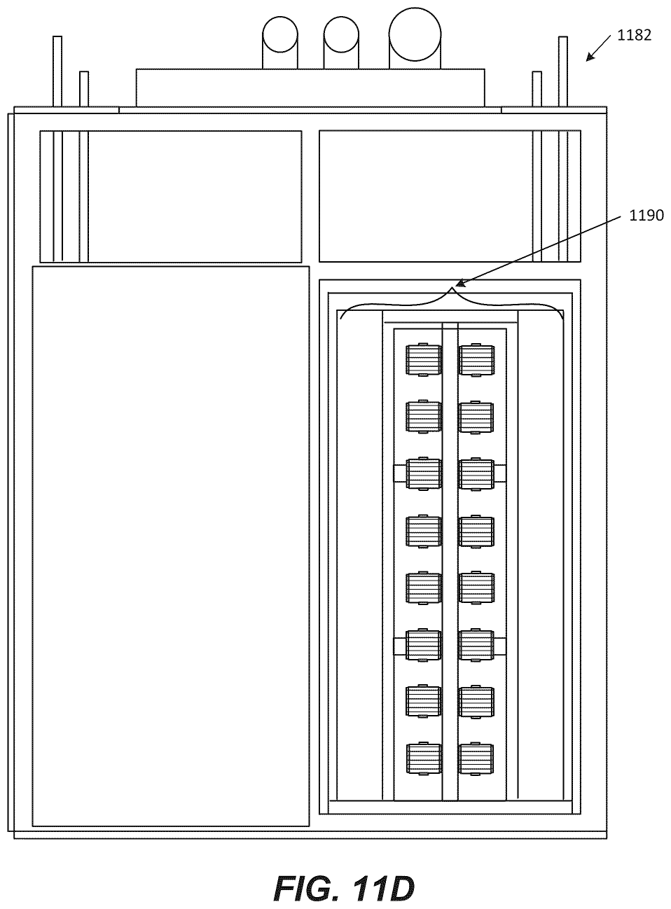

FIGS. 11A and 11B show examples of the cabinet system with blades and cryo-fluids provided by a cryo-plant, in accordance with some example embodiments. The flow system diagram in FIG. 11A illustrates how an example cabinet system 1100 connects to a cryoplant 1130, where the cabinet system 1100 includes a tower section 1110 (e.g., cryogenic blade tower 800, cryogenic blade tower 900) and a distribution top section 1105 that are in respective thermally shielded enclosures.

FIG. 11B illustrates an example cryogenic cabinet rack system 1170 in which side panels 1167 and a front panel 1166 of the perspective view of the system in FIG. 11B are transparent for illustrative purposes. The cryogenic cabinet rack system 1170 houses four separate blade towers, such as blade tower 1185. In some example embodiments, to install or remove components or the entire blade tower 1185, the front panel is removed. For example, the front panel 1166 can be removed (e.g., fasteners unscrewed, after venting the vacuum of the cryogenic cabinet rack system 1170 as discussed above, via a vent) to remove or otherwise access the blade tower 1185. The blade tower 1185 is then accessed with the panel removed. In some example embodiments, the blade tower 1185 is installed on rails and the tower cabinet is slid along the rails in the direction of arrows 1187. As an additional example, to access the tower adjacent to the blade tower 1185, another front panel 1174 (not transparent in FIG. 11B) of one of the additional cabinets 1172 can be removed and the tower components or tower cabinet itself can be installed or removed in a similar manner. In some example embodiments, each tower (e.g., blade tower 1185) is an enclosed cabinet that has a metal shell that separates it from other towers in the cryogenic cabinet rack system 1170. In some example embodiments, each tower is an open cabinet, where the cabinet includes the metal support structures and the cryo and room temperature blades. In the open cabinet configuration, all four cabinets share the same vacuum chamber space within the cryogenic cabinet rack system 1170 (e.g., when vacuum pumped, all four open cabinet towers are pumped at the same time). In some example embodiments, the cryogenic cabinet rack system 1170 includes dividing walls that separate each tower cabinet into its own area.

In some example embodiments, the cryo-cabinet rack system can be configured with any of the example blade embodiments discussed above (e.g., FIGS. 8A-8C, FIGS. 9A-9C). The different blade configurations have the congruent form factor and connectors such that different blade embodiments can be switched in and out in a single cryo-cabinet rack system. In some example embodiments, a single cryo-cabinet rack system may have different combinations of blade types within the same cryogenic cabinet rack system.

The devices and methods of the alternative embodiments have the following non-limiting advantages. The cryo-cabinet rack system is modularized to provide custom fit for different cooling and temperature requirements, from 2.2K to 70 mK. The cryo-cabinet rack system provides high density cryo-genic housing for chips per volume (e.g., 800 or more chips per cryo-cabinet rack system). The cryo-cabinet rack system has a higher cooling capacity (e.g., ˜200 W @ 2.2K) than other approaches (e.g., ˜3 W @ 2.2K). The cryo-cabinet rack system enables both room temperature and cryogenic electronic and optical sub-assemblies in a single vacuum chamber, thereby reducing the number of hermetic interconnects as compared to other approaches. Further, the room temperature and cryogenic electronic and optical sub-assemblies (e.g., blades) are closely located for reduced latency when communicating between sub-assemblies across the two temperature regimes. Further, the cryo-cabinet rack system includes easy-to-access panels to access a given tower in a cabinet, and each tower cabinet can be configured with a moveable track to facilitate assembly and maintenance. The cryo-cabinet rack system can be configured to have rack mount form factor (e.g., four 48RU racks). For example, each of the four towers in cryogenic cabinet rack system 1170 can be configured as a structure that has a similar or same shape and size as a rack mount enclosure (e.g., server rack; 36RU) 42RU, 45RU, 48RU rack; width of 24 to 40 inches, height of 70 to 100 inches, depth of 40 to 50 inches) for installation a plurality of cryo-cabinet rack systems into a data center.

FIG. 11C shows a cryo-blade cube system 1182, in accordance with some example embodiments. In the example illustrated, four blade systems (e.g., FIG. 9C) are inserted into four different tower or rack bays (e.g., denoted by “1”, “2”, “3”, “4”) and each cabinet can run within the cryo-blade cube system 1182. In some example embodiments, each entire blade system is swappable and can be removed from a given bay. Further, the cube can provide a plurality of cooling fluids through a coolant interface 1180 for the cryo-blade cube system 1182, such that all four of the blade systems receive and use the same coolant tanks for the cooling functions discussed above. FIG. 11D shows a front the of the cryo-blade cube system 1182, in accordance with some example embodiments. In the example illustrated, the door to bay 1 is closed and the door to bay 2 has been opened to access a cryo-blade system 1190 (depicted with the thermal shield transparent or removed as an example), as discussed above.

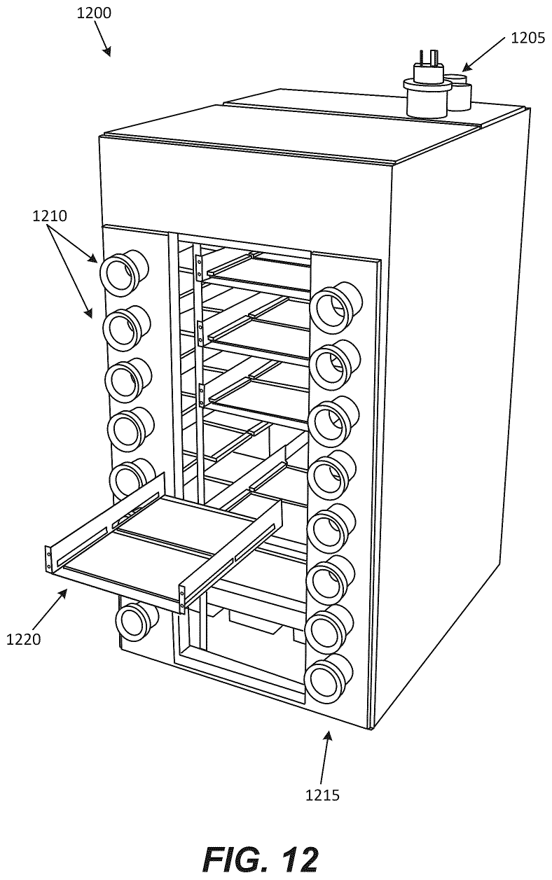

FIG. 12 shows an example cryogenic cabinet 1200 (e.g., cryogenic blade cabinet, cryogenic tray cabinet), in accordance with some example embodiments. In the example illustrated, cryogenic cabinet 1200 comprises a first plurality of physical ports 1210 and a second plurality of physical ports 1215 (e.g., vacuum feedthroughs). In some example embodiments, the physical ports can provide access for electronic and photonic cables to the interior of the cryogenic cabinet 1200 (e.g., to chips therein). In some example embodiments, cryogenic cabinet 1200 further comprises one or more coolant ports 1205 to provide coolant access (e.g., circulate liquid helium, circulate liquid nitrogen; remove helium in gas form, remove nitrogen in gas form) to regulate components and the inside cryogenic cabinet 1200. The coolant ports can be connected to any of the above cryogenic coolant distributions discussed above to receive and remove coolants, such as helium in liquid or gas form and nitrogen in liquid or gas form.

In some example embodiments, cryogenic cabinet 1200 further comprises insertable trays or enclosed modules. An example of the insertable units is illustrated as a plurality of trays 1220 in FIG. 12. In some example embodiments, each of the trays or modules comprises a set of electrical processing components (e.g., electronic chips, assemblies) and/or photonic processing components (e.g., PICs, assemblies) to perform information processing tasks (e.g., quantum photonic based information processing tasks; super-cooled cryogenic computing system tasks, artificial intelligence computing based tasks). In some example embodiments, each tray 1220 is a swapable computing unit of a photonic quantum computer that can be inserted and removed from a front of cryogenic cabinet 1200 as shown in FIG. 12. The bays into which the swappable computing units are inserted can include portions that insert into a cryogenic chamber that is maintained as a cryogenic temperature, as discussed in further detail below.

Although the cryogenic cabinet 1200 is illustrated in the example as a stack or tower in which horizontal trays are inserted into the stack to form a vertical stack, it is appreciated that other arrangements (e.g., horizontal tower with vertical trays or modules that form a row of columns) can be implemented in accordance with different physical design and space requirements of the computing system and data center.

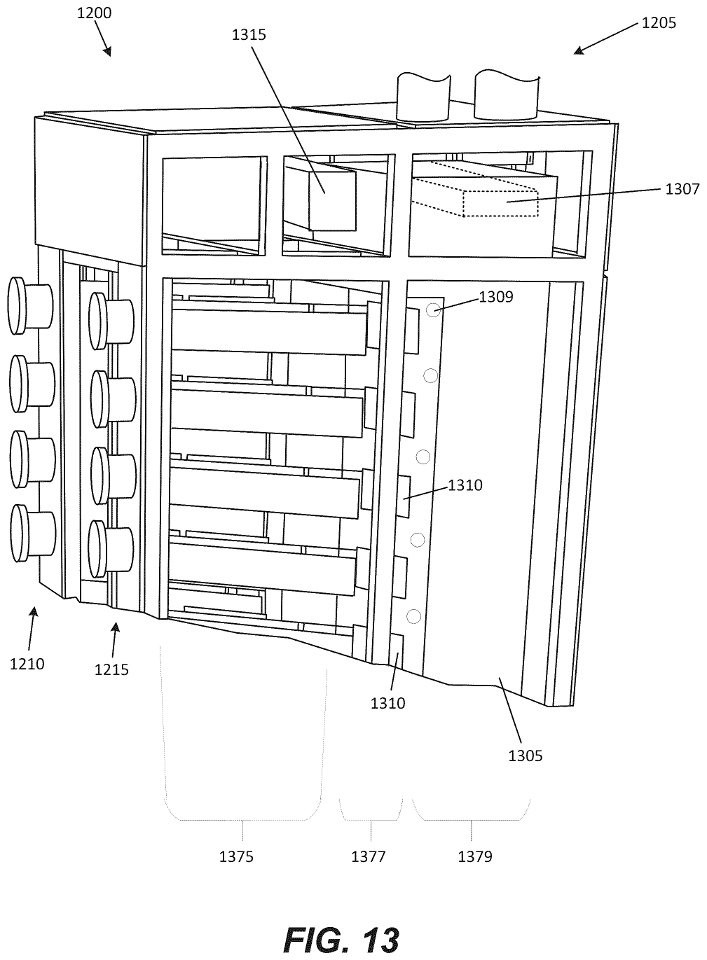

FIG. 13 shows a side perspective view of cryogenic cabinet 1200, in accordance with some example embodiments. In the example illustrated, one or more cooling liquids is input through the coolant ports 1205 for storage in one or more tanks of cryogenic cabinet 1200. For example, a first cryogenic coolant, such as liquid nitrogen, can be input and stored in a first vessel 1315 (e.g., liquid nitrogen tank), and a second cryogenic coolant, such as liquid helium, can be input and stored in a second vessel 1307 (liquid helium tank), depicted with dotted outlines as covered by a portion of the cryogenic chamber 1305 in FIG. 13. In some example embodiments, cryogenic cabinet 1200 comprises a cryogenic chamber 1305 to keep the contents inside the shield at a very cold temperatures, such as two to four degrees kelvin, using cryogenic coolants (e.g., liquid nitrogen, liquid helium). In some example embodiments, the first cryogenic coolant inside the first vessel 1315 is used to provide cooling to a front side of the cryogenic chamber 1305 (e.g., cryogenic temperature shield). In this way, the front side of the cryogenic temperature shield functions as a cryogenic temperature buffer that uses cryogenic cooling at a first higher temperature (e.g., 77 K) to shield a colder area at a second lower temperature (e.g., 2K, 4K).

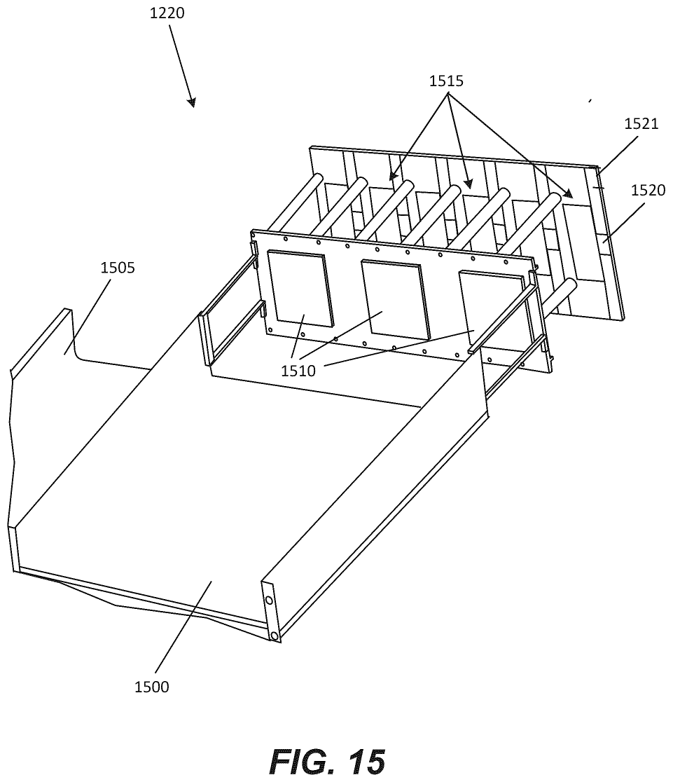

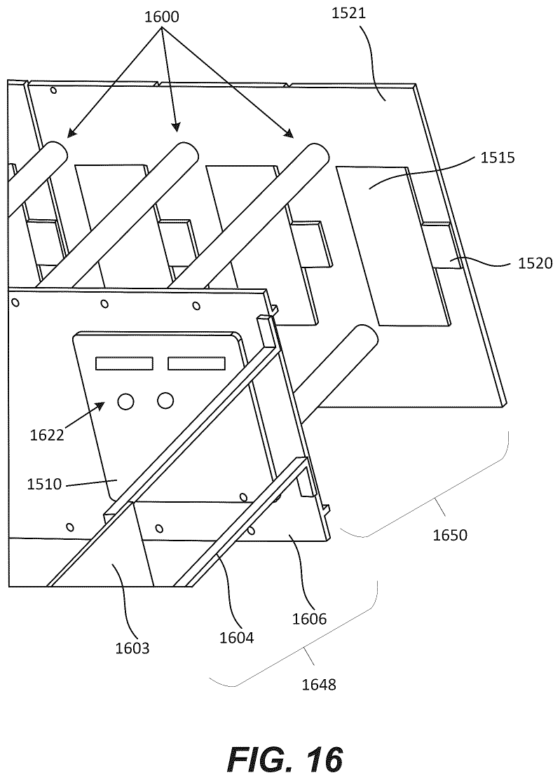

In some example embodiments, the first cryogenic coolant from the first vessel 1315 is provided to circulator plates 1310 (e.g., circulator plate 1510, FIG. 15) on a plate on each separate cryo tray. When the trays are inserted into openings of the cryogenic chamber 1305, the plate on which a given trays cooling plates are mounded (e.g., first plate 1606, FIG. 16) align with the front facing side of the cryogenic chamber 1305 to seal off the chamber and to provide cooling to the front side of the cryogenic chamber 1305 for buffering functionality. In some example embodiments, the cooling plate are not included in the each tray, and instead the front side of the cryogenic chamber 1305 is fluidly coupled to the first vessel 1315 (liquid nitrogen tank) via a plurality of ports (e.g., port 1309), pipes, and a cold plate (e.g., nitrogen cool plate) in the front side of cryogenic chamber 1305 to provide cooling to the front side of the cryogenic chamber 1305.

In this way, a given tray of the cabinet can comprise a first area 1375 that has components that can operate at room temperature (e.g., 300 K), a cryo-based buffer area 1377 (thermal shield) created by the first cryogenic coolant (e.g., liquid nitrogen) cooling a front portion and one or circulation plates, and a second area 1379 that comprises components that operate at super cold cryogenic temperatures (e.g., 2-4K) by application of the second cryogenic coolant (e.g., liquid helium) from the second vessel 1307.

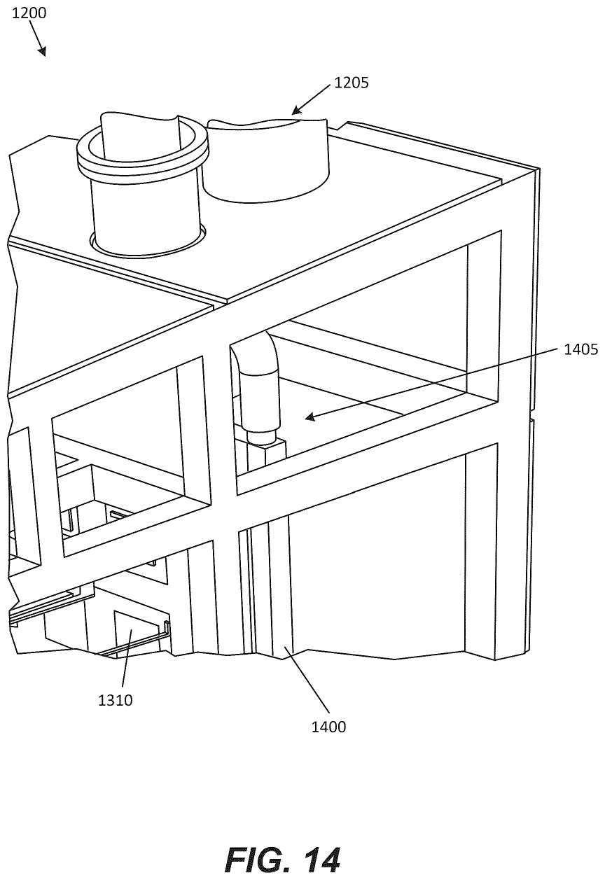

FIG. 14 shows a close-up of cryogenic cabinet 1200 with some portions removed to display internal components, in accordance with some example embodiments. As shown in the example of FIG. 14, cryogenic cabinet 1200 can comprise piping 1405 that is fluidly coupled to the second vessel 1307 (not shown in FIG. 14). The piping 1405 receives the second cryogenic coolant (e.g., liquid helium) and circulates the coolant in a circulation wall 1400 to cool items that are thermally coupled to the circulation wall 1400 (e.g., 2.2K cold plate). For example, backside plate of each tray (e.g., second plate 1521, FIG. 15) of each tray can be thermally coupled (e.g., pressed against) to the circulation wall 1400 when the trays are inserted fully into the cryogenic cabinet 1200. Although only one piping 1405 is in FIG. 14, in some example embodiments, an additional piping (e.g., feed through) first transfers the liquid helium from vessel 1307 to the bottom side of circulation wall 1400, and the helium is then circulated through the circulation wall 1400 to provide cryogenic cooling and transferred back to the vessel 1307 using the piping 1405.

FIG. 15 shows an example tray 1220 that can be inserted in cryogenic cabinet 1200 (not shown in FIG. 15), in accordance with some example embodiments. In the example of FIG. 15, the tray 1220 operates as one piece that can be inserted and removed from the cabinet, although, as discussed below, in some embodiments, portions of the tray, such as the heat sync 1505 may remain in the cabinet while the rest of the tray 1220 is removable. When inserted, each tray 1220 can provide operating conditions for three temperature zones: a room temperature area (e.g., 300K), a 77K area (heat shield), and a 2K area. Further, each tray can support multiple classes of chips including non-cryogenic chips in a first tray area 1500 that operate at non-cryogenic temperatures (e.g., room temperature, 300K), and cryogenic chips (e.g., PIC 1520) on a second area of the second plate 1521 (e.g., metal plate, copper plate) that operate at a cryogenic temperature (2K). As illustrated, the tray 1220 comprises a first tray area 1500 that can hold computing components that operate at non-cryogenic temperature, such as room or ambient temperature (e.g., electrical logic circuits, ASICs, CPUs, GPUs, assemblies thereof). In some example embodiments, the first tray area 1500 is attached to a heat sync 1505 (e.g., metal heat syncs, copper syncs) to remove heat from the first tray area 1500. In some example embodiments, the first tray area 1500 is not attached to the heat sync 1505 and instead the heat sync 1505 remains in the cryogenic cabinet 1200. In those example embodiments, when the tray 1220 is inserted into the cryogenic cabinet 1200 a side of the tray comes into contact with the heat sync 1505 for thermal coupling and wicking of heat.

Further illustrated in FIG. 15 are cooling shield circulator units (e.g., circulator plate 1510; circulator plates 1310, FIG. 13) that receive and circulate the first cryogenic coolant (e.g., liquid Nitrogen) to create a cryogenic temperature barrier between a room temperature area (e.g., of first tray area 1500, first area 1375, FIG. 13) and a super cryogenic temperature area (e.g., 2K area; second area 1379, FIG. 13) of the environment inside the shield (e.g., cryogenic chamber 1305, FIG. 13) in which electrical circuits 1515 (e.g., electronic chips, boards) and photonic integrated circuits 1520 operate to perform quantum computing functions (e.g., generation of single photons, photon detection, switching), in accordance with some example embodiments.

FIG. 16 shows a close-up of portions of the tray 1220, in accordance with some example embodiments. The tray 1220 can include a first plate 1606 and first post structures 1603 that separate the room temperature portions of the tray (e.g., tray area 1500) from a first plate 1606 that, when the tray is inserted, forms part of the cryogenic thermal shield with a room temperature buffer area 1648 separating room temperature components from the thermal shield. As shown, the first plate 1606 includes the circulator plate 1510 that circulate liquid nitrogen. Further, in the example shown in FIG. 16, the tray 1220 includes ridged post structures 1600 that separate the first plate 1606, upon which the cooling shield circulator units are attached, from the second plate 1521. The second plate 1521 houses the cryogenic circuits, such as the electrical circuits 1515 and the PIC 1520, which are designed to function at cryogenic temperatures, such as 2K. The rigid post structures 1600 create a cryogenic buffer region 1650 (e.g., empty space buffer region) between the first plate 1606 and circulator plate 1510 and the second plate 1521 that has the supercooled cryogenic computing units (e.g., photonic integrated circuit 1520). In some example embodiments, the first tray area 1500 is separated from the circulator plate 1510 by a support structure 1604 for further spacing and thermal separation. The close-up view of FIG. 16 further illustrates the cooling plate conduits 1622 (e.g., connectors, circulation channels, pipes) of the circulator plate 1510 for cooling the circulator plate 1510 to 77K using the first cryogenic coolant (e.g., using liquid nitrogen from the liquid nitrogen vessel). In some example embodiments, a tray is inserted into the cabinet and attached or fixed using clamps or screws (e.g., screwing the first plate 1606 so it is fixed to the thermal shield to create a seal for thermal shield interior area, where the second plate 1521 is not fixed but is rather pressed against or otherwise thermally coupled to the 2K cold plate once the first plate is screwed in). Once the tray is inserted and fixed, cables from the nitrogen vessel can be connected to the cooling plate conduits 1622 to circulate coolant (e.g., liquid nitrogen) to each of a tray's cold plate thereby regulating the cryogenic thermal shield across all plates of all the trays. While in some example embodiments, the first plate 1606 does not include circulator units and is instead a single piece of material, such as copper. In those example embodiments, the first coolant is circulated in a front portion of the cryogenic chamber (e.g., the thermal shield) to cool the front portion of the cryogenic chamber and all of the first places of the inserted trays, such that they operate thermally in concert as a cryogenic thermal shield for the chips on the second plate 1521.

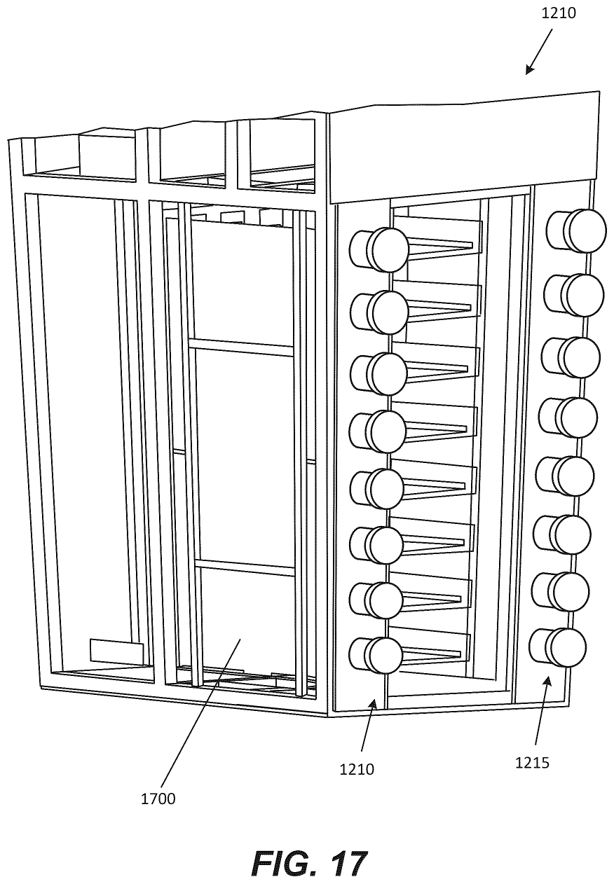

FIG. 17 shows a side perspective view of cryogenic cabinet 1200, in accordance with some example embodiments. In FIG. 17, a heat exchanger 1700 (e.g., metal heat sync, water circulation system, dielectric liquid circulation system) is shown on a left side of the cabinet to wick heat and regulator the temperature of the non-cryogenic components (e.g., maintain them at room temperature). The heat exchanger 1700 (e.g., room temperature heat exchanger, room temperature dielectric fluid circulation system) can physically attach or connect with each tray's individual metal heat sync (e.g., heat sync 1505, FIG. 15) to wick heat away from each tray and maintain a temperature of the tray's operating components (e.g., chips) within a target operating range (e.g., 290 to 310 Kelvin). In some example embodiments, the cryogenic cabinet 1200 comprises vents and one or more fans to provide air cooling to the components in the cryogenic cabinet 1200 (e.g., to wick away heat from tray heat syncs or heat exchanger 1700).

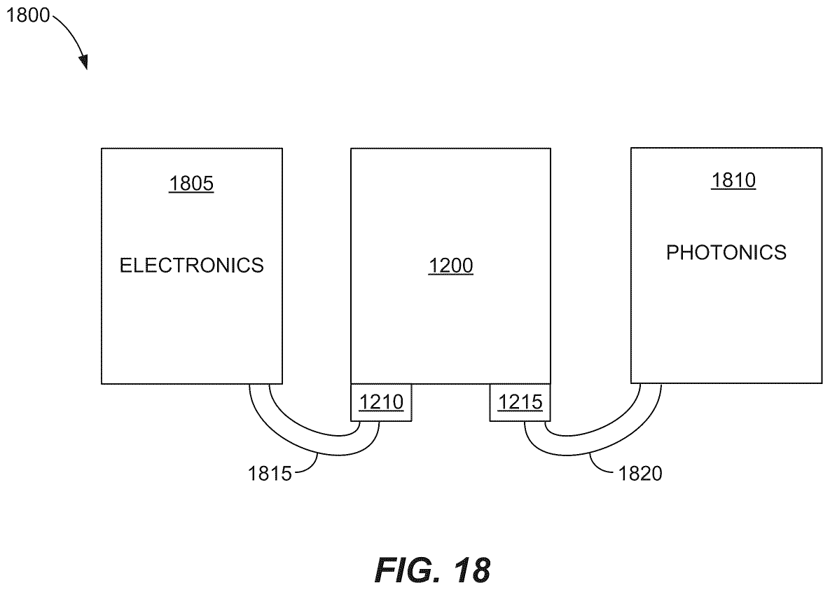

FIG. 18 shows a control system architecture 1800, in accordance with some example embodiments. In the example illustrated, cryogenic cabinet 1200 interfaces with an electronics control unit 1805 that is on the left side of cryogenic cabinet 1200, and a photonics control unit 1810 that is on a right side of cryogenic cabinet 1200. In some example embodiments, the photonics control unit 1810 comprises a plurality of light sources (e.g., replicated classical pulses, pulse replicators, spontaneous parametric down conversion PIC sources, four wave mixing PIC sources) that provide light (e.g., classical light pulses, single photons, pairs of photons) to cryogenic cabinet 1200 to perform quantum photonic processing. The light can be input into cryogenic cabinet 1200 using one or more fiber-optic cables 1820 that are fed through the physical ports 1215 (e.g., vacuum feedthroughs). In some example embodiments, the electronics control unit 1805 comprises electrical controllers (e.g., classical computers, CPUs, FGPAs, GPUs) to control of the computing units inside cryogenic cabinet 1200 via control cables 1815 (e.g., electrical data cables, cords), and the photonic components in the photonics control unit 1810. In some example embodiments, the electronic control unit 1805 further comprises one or more display screens and input/output devices (e.g., keyboard, mouse) to provide human user interface to the control system architecture 1800 to perform administrative tasks and initiate quantum computation tasks.

Example 1: A system comprising: a cryogenic cabinet comprising a plurality of coolant ports and a cryogenic chamber, the plurality of coolant ports comprising a first channel to circulate a first cryogenic coolant for cooling a first temperature area of the cryogenic cabinet to a first cryogenic temperature, and a second channel to circulate a second cryogenic coolant for cooling a second temperature area of the cryogenic cabinet to a second cryogenic temperature, the second cryogenic temperature being colder than the first cryogenic temperature; and a plurality of trays that are insertable into the cryogenic cabinet, a tray of the plurality of trays comprising a first area comprising non-cryogenic circuits that operate at a non-cryogenic temperature, the tray further comprising a second area comprising cryogenic circuits that operate a cryogenic temperature of the second cryogenic coolant, the cryogenic chamber comprising a thermal shield that is cooled to the first cryogenic temperature of the first cryogenic coolant, the thermal shield forming a cryogenic heat buffer between first areas of the plurality of trays and second areas of the plurality of trays such that the cryogenic circuits are maintained at the second cryogenic temperature of the second cryogenic coolant.

Example 2: The system as example 1 describes, wherein each tray of the plurality of trays comprises a heat sync that maintain the first area of the tray at the non-cryogenic temperature such that the non-cryogenic circuits of the tray operate at the non-cryogenic temperature as maintained by the heat sync while the cryogenic circuits of the tray operate at the cryogenic temperature as maintained by the second cryogenic coolant and as thermally buffered by the first cryogenic coolant that cools portions of the thermal shield to the first cryogenic temperature.

Example 3: The system as either of examples 1 or 2 describe, wherein the heat sync is a metallic heat sync that is cooled by air currents in the cryogenic cabinet.

Example 4: The system as any of examples 1-3 describe, wherein the heat sync is a metallic heat sync that is cooled by a non-cryogenic circulation system.

Example 5: The system as any of examples 1-4 describe, wherein the non-cryogenic circulation system comprises a water circulation system.

Example 6: The system as any of examples 1-5 describe, wherein the cryogenic cabinet comprises guides to guide each tray of the plurality of trays into the cryogenic cabinet.

Example 7: The system as any of examples 1-6 describe, wherein the first cryogenic coolant comprises nitrogen.

Example 8: The system as any of examples 1-7 describe, wherein the second cryogenic coolant comprises helium.

Example 9: The system as any of examples 1-8 describe, wherein each tray

comprises a plate that separates the first area of the tray from the second area of the tray.

Example 10: The system as any of examples 1-9 describe, wherein the cryogenic chamber comprises a plurality of openings into which portions of the plurality of trays can be inserted.

Example 11: The system as any of examples 1-10 describe, wherein the plate of the tray closes one of the plurality of openings when the tray is inserted into the one of the plurality of openings.

Example 12: The system as any of examples 1-11 describe, wherein the plate is a first plate, and the tray comprises a second plate that comprises the cryogenic circuits.

Example 13: The system as any of examples 1-12 describe, wherein the cryogenic chamber comprises a cold plate that is cooled to the second cryogenic temperature by the second cryogenic coolant, and wherein the second plate of the tray is thermally coupled to the cold plate to cool the second plate to the second cryogenic temperature.

Example 14: The system as any of examples 1-13 describe, wherein the plate of the tray comprises fluid conduits to circulate the first cryogenic coolant to cool the plate to the first cryogenic temperature to form the cryogenic heat buffer.

Example 15: The system as any of examples 1-14 describe, wherein the cryogenic chamber comprises fluid conduits that circulates the first cryogenic coolant to circulator plates of different trays and a front side of the cryogenic chamber to the first cryogenic temperature to form the cryogenic heat buffer.

Example 16: The system as any of examples 1-15 describe, wherein the first cryogenic temperature and the second cryogenic temperature are below 120 degrees Kelvin.

Example 17: The system as any of examples 1-16 describe, wherein the first cryogenic temperature comprises 77 degrees Kelvin and the second cryogenic temperature comprises 4 Kelvin.

Example 18: The system as any of examples 1-17 describe, wherein the first cryogenic temperature comprises 77 degrees Kelvin and the second cryogenic temperature comprises 2 Kelvin.

Example 19: The system as any of examples 1-18 describe, further comprising: a first vessel to store the first cryogenic coolant and to provide and remove the first cryogenic coolant in the cryogenic cabinet; and a second vessel to store the second cryogenic coolant and to provide and remove the second cryogenic coolant in the cryogenic cabinet.

Example 20: The system as any of examples 1-19 describe, wherein the plurality of trays are horizontal trays and the plurality of trays are arranged in a vertical stack when inserted into the cryogenic cabinet.

Example 21: The system as any of examples 1-20 describe, wherein the plurality of trays are vertical trays and the plurality of trays are arranged as a row of columns when inserted into the cryogenic cabinet.

Example 22: The system as any of examples 1-21 describe, wherein each tray comprises a first plate and a second plate, and wherein the first plate and second plate and the cryogenic chamber are metal.

Example 23: The system as any of examples 1-22 describe, wherein the cryogenic chamber is sealed by the plurality of trays that are inserted into the cryogenic chamber, and wherein the cryogenic chamber is in pumped to a vacuum state to reduce heat current flow in the cryogenic chamber.

Example 24: A method comprising: inserting a plurality of trays into a cryogenic cabinet, the cryogenic cabinet comprising a plurality of coolant ports and a cryogenic chamber, the plurality of coolant ports comprising a first channel to circulate a first cryogenic coolant for cooling a first temperature area of the cryogenic cabinet to a first cryogenic temperature, and a second channel to circulate a second cryogenic coolant for cooling a second temperature area of the cryogenic cabinet to a second cryogenic temperature, the second cryogenic temperature being colder than the first cryogenic temperature, and a tray of the plurality of trays comprising a first area comprising non-cryogenic circuits that operate at a non-cryogenic temperature, the tray further comprising a second area comprising cryogenic circuits that operate a cryogenic temperature of the second cryogenic coolant; cooling a thermal shield of the cryogenic chamber to the first cryogenic temperature using the first cryogenic coolant; cooling a cold plate of the cryogenic chamber to the second cryogenic temperature using the second cryogenic coolant; and operating the non-cryogenic circuits at the non-cryogenic temperature while operating the cryogenic circuits at the second cryogenic temperature, the thermal shield forming a cryogenic heat buffer between first areas of the plurality of trays and second areas of the plurality of trays such that the cryogenic circuits are maintained at the second cryogenic temperature of the second cryogenic coolant.

Example 25: The method as example 24 describes, wherein each tray of the plurality of trays comprises a heat sync that maintain the first area of the tray at the non-cryogenic temperature such that the non-cryogenic circuits of the tray operate at the non-cryogenic temperature as maintained by the heat sync while the cryogenic circuits of the tray operate at the cryogenic temperature as maintained by the second cryogenic coolant and as thermally buffered by the first cryogenic coolant that cools portions of the thermal shield to the first cryogenic temperature.

Example 26: The method as either of examples 24 or 25 describe, wherein the heat sync is a metallic heat sync that is cooled by air currents in the cryogenic cabinet.

Example 27: The method as any of examples 24-26 describe, wherein the heat sync is a metallic heat sync that is cooled by a non-cryogenic circulation method.

Example 28: The method as any of examples 24-27 describe, wherein the non-cryogenic circulation method comprises a water circulation method.

Example 29: The method as any of examples 24-28 describe, wherein the cryogenic cabinet comprises guides to guide each tray of the plurality of trays into the cryogenic cabinet.

Example 30: The method as any of examples 24-29 describe, wherein the first cryogenic coolant comprises nitrogen.

Example 31: The method as any of examples 24-30 describe, wherein the second cryogenic coolant comprises helium.

Example 32: The method as any of examples 24-31 describe, wherein each tray comprises a plate that separates the first area of the tray from the second area of the tray.

Example 33: The method as any of examples 24-32 describe, wherein the cryogenic chamber comprises a plurality of openings into which portions of the plurality of trays can be inserted.

Example 34: The method as any of examples 24-33 describe, wherein the plate of the tray closes one of the plurality of openings when the tray is inserted into the one of the plurality of openings.

Example 35: The method as any of examples 24-34 describe, wherein the plate is a first plate, and the tray comprises a second plate that comprises the cryogenic circuits.

Example 36: The method as any of examples 24-35 describe, wherein the cryogenic chamber comprises a cold plate that is cooled to the second cryogenic temperature by the second cryogenic coolant, and wherein the second plate of the tray is thermally coupled to the cold plate to cool the second plate to the second cryogenic temperature.

Example 37: The method as any of examples 24-36 describe, wherein the plate of the tray comprises fluid conduits to circulate the first cryogenic coolant to cool the plate to the first cryogenic temperature to form the cryogenic heat buffer.

Example 38: The method as any of examples 24-37 describe, wherein the cryogenic chamber comprises fluid conduits that circulates the first cryogenic coolant to circulator plates of different trays and a front side of the cryogenic chamber to the first cryogenic temperature to form the cryogenic heat buffer.

Example 39: The method as any of examples 24-38 describe, wherein the first cryogenic temperature and the second cryogenic temperature are below 120 degrees Kelvin.

Example 40: The method as any of examples 24-39 describe, wherein the first cryogenic temperature comprises 77 degrees Kelvin and the second cryogenic temperature comprises 4 Kelvin.

Example 41: The method as any of examples 24-40 describe, wherein the first cryogenic temperature comprises 77 degrees Kelvin and the second cryogenic temperature comprises 2 Kelvin.

Example 42: The method as any of examples 24-41 describe, further comprising: a first vessel to store the first cryogenic coolant and to provide and remove the first cryogenic coolant in the cryogenic cabinet; and a second vessel to store the second cryogenic coolant and to provide and remove the second cryogenic coolant in the cryogenic cabinet.

Example 43: The method as any of examples 24-42 describe, wherein the plurality of trays are horizontal trays and the plurality of trays are arranged in a vertical stack when inserted into the cryogenic cabinet.

Example 44: The method as any of examples 24-43 describe, wherein the plurality of trays are vertical trays and the plurality of trays are arranged as a row of columns stack when inserted into the cryogenic cabinet.

Example 45: The method as any of examples 24-44 describe, wherein each tray comprises a first plate and a second plate, and wherein the first plate and second plate and the cryogenic chamber are metal.

Example 46: The method as any of examples 24-45 describe, wherein the cryogenic chamber is sealed by the plurality of trays that are inserted into the cryogenic chamber, and wherein the cryogenic chamber is in pumped to a vacuum state to reduce heat current flow in the cryogenic chamber.

The terminology used in the description of the various described embodiments herein is for the purpose of describing particular embodiments only and is not intended to be limiting. As used in the description of the various described embodiments and the appended claims, the singular forms “a”, “an” and “the” are intended to include the plural forms as well, unless the context clearly indicates otherwise. It will also be understood that the term “and/or” as used herein refers to and encompasses any and all possible combinations of one or more of the associated listed items. It will be further understood that the terms “includes,” “including,” “comprises,” and/or “comprising,” when used in this specification, specify the presence of stated features, integers, steps, operations, elements, and/or components, but do not preclude the presence or addition of one or more other features, integers, steps, operations, elements, components, and/or groups thereof.

As used herein, the term “if” is, optionally, construed to mean “when” or “upon” or “in response to determining” or “in response to detecting” or “in accordance with a determination that,” depending on the context.

The foregoing description, for purpose of explanation, has been described with reference to specific embodiments. However, the illustrative discussions above are not intended to be exhaustive or to limit the scope of the claims to the precise forms disclosed. Many modifications and variations are possible in view of the above teachings. The embodiments were chosen in order to best explain the principles underlying the claims and their practical applications, to thereby enable others skilled in the art to best use the embodiments with various modifications as are suited to the particular uses contemplated.

It is also understood that the examples and embodiments described herein are for illustrative purposes only and that various modifications or changes in light thereof will be suggested to persons skilled in the art and are to be included within the spirit and purview of this application and scope of the appended claims.

What is claimed is:

1. A system comprising:
a cryogenic cabinet comprising a plurality of coolant ports and a cryogenic chamber, the plurality of coolant ports comprising a first channel to circulate a first cryogenic coolant for cooling a first temperature area of the cryogenic cabinet to a first cryogenic temperature, and a second channel to circulate a second cryogenic coolant for cooling a second temperature area of the cryogenic cabinet to a second cryogenic temperature, the second cryogenic temperature being colder than the first cryogenic temperature; and
a plurality of units that are insertable into the cryogenic cabinet, a unit of the plurality of unit comprising a first area comprising non-cryogenic circuits that operate at a non-cryogenic temperature, the unit further comprising a second area comprising cryogenic circuits that operate a cryogenic temperature of the second cryogenic coolant, the cryogenic chamber comprising a thermal shield that is cooled to the first cryogenic temperature of the first cryogenic coolant, the thermal shield forming a cryogenic heat buffer between first areas of the plurality of units and second areas of the plurality of units such that the cryogenic circuits are maintained at the second cryogenic temperature of the second cryogenic coolant.

2. The system of claim 1, wherein each unit of the plurality of units comprises a heat sync that maintain the first area of the unit at the non-cryogenic temperature such that the non-cryogenic circuits of the unit operate at the non-cryogenic temperature as maintained by the heat sync while the cryogenic circuits of the unit operate at the cryogenic temperature as maintained by the second cryogenic coolant and as thermally buffered by the first cryogenic coolant that cools portions of the thermal shield to the first cryogenic temperature.

3. The system of claim 2, wherein the heat sync is a metallic heat sync that is cooled by air currents in the cryogenic cabinet.

4. The system of claim 2, wherein the heat sync is a metallic heat sync that is cooled by a non-cryogenic circulation system.

5. The system of claim 4, wherein the non-cryogenic circulation system comprises a water circulation system.

6. The system of claim 2, wherein the cryogenic cabinet comprises guides to guide each unit of the plurality of units into the cryogenic cabinet.

7. The system of claim 1, wherein the first cryogenic coolant comprises nitrogen.

8. The system of claim 1, wherein the second cryogenic coolant comprises helium.

9. The system of claim 1, wherein each unit of the plurality of units comprises a plate that separates the first area of the unit from the second area of the unit.

10. The system of claim 9, wherein the cryogenic chamber comprises a plurality of openings into which portions of the plurality of units can be inserted.

11. The system of claim 10, wherein the plate of the unit closes one of the plurality of openings when the unit is inserted into the one of the plurality of openings.

12. The system of claim 9, wherein the plate is a first plate, and the unit comprises a second plate that comprises the cryogenic circuits.

13. The system of claim 12, wherein the cryogenic chamber comprises a cold plate that is cooled to the second cryogenic temperature by the second cryogenic coolant, and wherein the second plate of the unit is thermally coupled to the cold plate to cool the second plate to the second cryogenic temperature.

14. The system of claim 9, wherein the plate of the unit comprises fluid conduits to circulate the first cryogenic coolant to cool the plate to the first cryogenic temperature to form the cryogenic heat buffer.

15. The system of claim 1, wherein the cryogenic chamber comprises fluid conduits that circulates the first cryogenic coolant to circulator plates of different units and a front side of the cryogenic chamber to the first cryogenic temperature to form the cryogenic heat buffer

16. The system of claim 1, wherein the first cryogenic temperature and the second cryogenic temperature are below 120 degrees Kelvin.

17. The system of claim 1, wherein the first cryogenic temperature comprises 77 degrees Kelvin and the second cryogenic temperature comprises 4 Kelvin.

18. The system of claim 1, wherein the first cryogenic temperature comprises 77 degrees Kelvin and the second cryogenic temperature comprises 2 Kelvin.

19. The system of claim 1, further comprising:
a first vessel to store the first cryogenic coolant and to provide and remove the first cryogenic coolant in the cryogenic cabinet; and
a second vessel to store the second cryogenic coolant and to provide and remove the second cryogenic coolant in the cryogenic cabinet.

20. The system of claim 1, wherein the plurality of units are horizontal units and the plurality of units are arranged in a vertical stack when inserted into the cryogenic cabinet.
